(19) United States
(12) Patent Application Publication
(10) Pub. No.: US 2026/0136594 A1
(43) Pub. Date: May 14, 2026

(54) SEMICONDUCTOR DEVICE AND METHODS OF FORMING THE SAME

(71) Applicant: TAIWAN SEMICONDUCTOR MANUFACTURING COMPANY, LTD., Hsinchu (TW)

(72) Inventor: Tzu-Ging LIN, Kaohsiung (TW)

(21) Appl. No.: 18/940,949

(22) Filed: Nov. 8, 2024

(51) Int. Cl. H01L 29/417; H01L 21/283; H01L 21/311; H01L 23/528; H01L 29/06; H01L 29/423; H01L 29/66; H01L 29/775; H01L 29/786

(52) U.S. Cl. CPC H10D 30/6729; H10P 14/40; H10W 20/43; H10D 30/014; H10D 30/43; H10D 30/6735; H10D 30/6757; H10D 62/121; H10P 50/28

(57) ABSTRACT

Embodiments of the present disclosure provide a semiconductor device that includes a substrate having a frontside and a backside opposite to the frontside of the substrate; a channel region disposed between a first source/drain region and a second source/drain region and over the frontside of the substrate; a gate structure disposed over the channel region; and a first contact disposed in the substrate, wherein the first contact includes a first sidewall extending from the backside of the substrate and a second sidewall extending to the first source/drain region, wherein the first sidewall and the second sidewall are on a same side of the first contact, wherein the second sidewall is horizontally more distant away from the second source/drain region along a vertical direction from the backside of the substrate toward the first source/drain region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of intermediate stages of manufacturing a semiconductor device, in accordance with some embodiments.

FIGS. 7A-25B are cross-sectional views of intermediate stages of manufacturing a semiconductor device, in accordance with some embodiments.

FIGS. 26A-30B are cross-sectional views of intermediate stages of manufacturing a semiconductor device, in accordance with some embodiments.

FIGS. 31A-34B are cross-sectional views of intermediate stages of manufacturing a semiconductor device, in accordance with some embodiments.

FIGS. 35A and 35B are cross-sectional views of intermediate stages of manufacturing a semiconductor device, in accordance with some embodiments.

FIGS. 36A and 36B are cross-sectional views of intermediate stages of manufacturing a semiconductor device, in accordance with some embodiments.

FIGS. 37-40B are perspective views and cross-sectional views of intermediate stages of manufacturing a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide a semiconductor device including self-aligned backside contacts formed in the substrate and electrically coupled to source/drain regions. The self-aligned backside contacts formed in a self-aligned manner can effectively reduce the risks of damaging gate structures or forming shorts between the backside contacts and gate structures.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, FinFETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning, or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

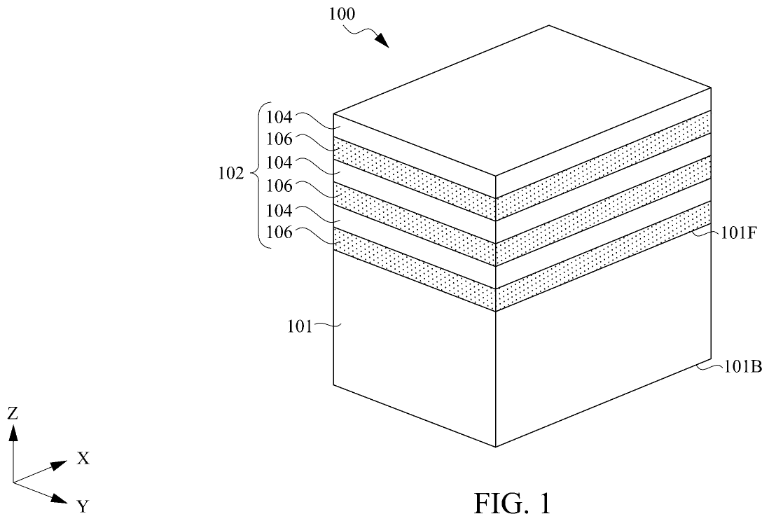

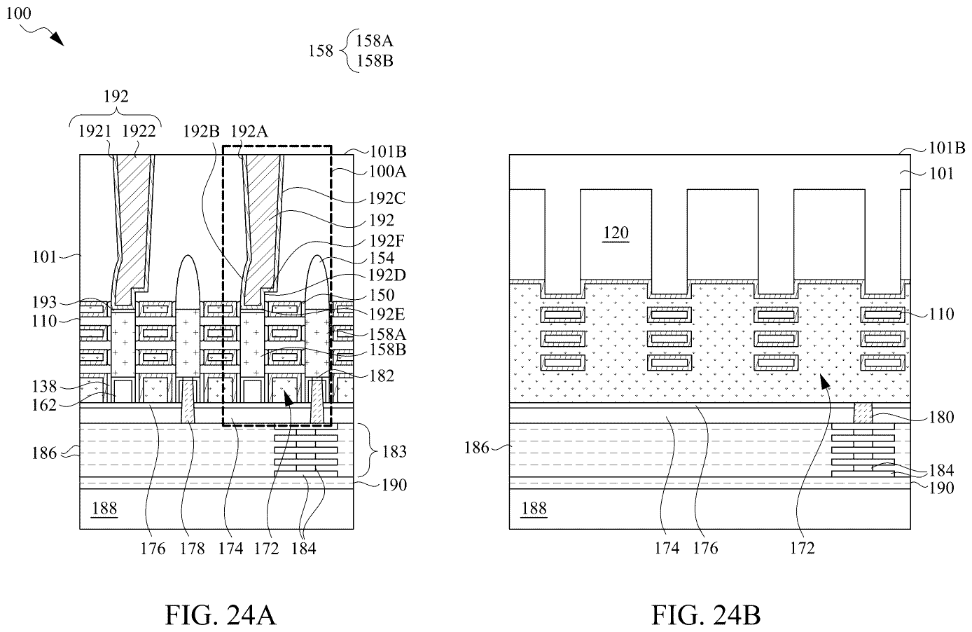

FIGS. 1-25B show exemplary processes for manufacturing a semiconductor device 100 according to embodiments of the present disclosure. It is understood that additional operations can be provided before, during, and after processes shown by FIGS. 1-25B, and some of the operations described below can be replaced or eliminated, for additional embodiments of the method. The order of the operations/processes is not limiting and may be interchangeable.

FIGS. 1-6 are perspective views of intermediate stages in manufacturing a semiconductor device 100, in accordance with some embodiments. As shown in FIG. 1, a semiconductor device 100 includes a substrate 101 having a frontside 101F and a backside 101B opposite to the frontside 101F. The semiconductor device 100 also includes a multilayer stack 102 formed over the frontside 101F of the substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity) in the frontside 101F of the substrate 101. Depending on circuit design, the substrate 101 may include p-type doped wells for an n-type field effect transistors (NFET) n-type doped wells for a p-type field effect transistors (PFET).

The multilayer stack 102 includes alternating semiconductor layers made of different materials to facilitate the formation of nanostructure channels in a multi-gate device, such as nanostructure channel FETs. In some embodiments, the multilayer stack 102 includes first semiconductor layers 104 and second semiconductor layers 106 that are alternately stacked over the frontside 101F of the substrate 101. For example, the multilayer stack 102 is illustrated as including three layers of first semiconductor layers 104 and three layers of second semiconductor layers 106 for illustrative purposes. It is appreciated that any number of the first and second semiconductor layers 104, 106 can be included in the multilayer stack 102. In some embodiments, the first semiconductor layers 104 are formed of a first semiconductor material, and the second semiconductor layers 106 are formed of a second semiconductor material different from the first semiconductor material. The second semiconductor material may have a different etch selectively and/or oxidation rate than the first semiconductor material. In some embodiments, either the first semiconductor material or the second semiconductor material is or includes a material such as SiGe, SiC, GeAs, GaP, InP, InAs, InSb, GaAsP, AlInAs, AlGaAs, InGaAs, GaInP, GaInAsP, combinations thereof, or the like. In some embodiments, the first semiconductor material is formed of Si, and the second semiconductor material is formed of SiGe, or vice versa.

Each first semiconductor layer 104 may have a thickness in a range between about 5 nm and about 30 nm. Each second semiconductor layer 106 may have a thickness that is equal, less, or greater than the thickness of the first semiconductor layer 104. In some embodiments, each second semiconductor layer 106 has a thickness in a range between about 2 nm and about 50 nm. The first and second semiconductor layers 104, 106 are formed by any suitable deposition process, such as epitaxy deposition. By way of example, the epitaxial deposition of the multilayer stack 102 may be performed by vapor-phase epitaxy (VPE), molecular beam epitaxy (MBE), chemical vapor deposition (CVD), low-pressure metalorganic chemical vapor deposition (MOCVD) process, atomic layer deposition (ALD), the like, and/or other suitable epitaxial growth processes.

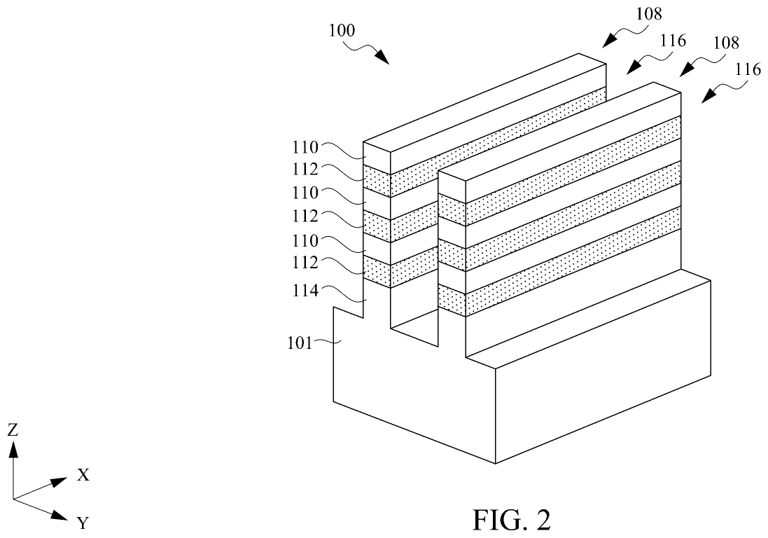

In FIG. 2, the multilayer stack 102 and the substrate 101 are patterned by one or more etch processes, in accordance with some embodiments. Each semiconductor strip 108 may include first nanostructures 110 patterned from the first semiconductor layers 104 and second nanostructures 112 patterned from the second semiconductor layers 106. The substrate 101 may include a plurality of fins 114 after the etch processes. The semiconductor strips 108 are disposed over the fins 114, respectively. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section.

The semiconductor strips 108 may be formed by patterning a hard mask layer (not shown) formed on the multilayer stack 102 using multi-patterning operations that include lithography and etch processes. The etch process can include dry etching such as reactive ion etching (RIE) or neutral beam etching (NBE), wet etching, and/or other suitable processes. The lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etch process forms trenches 116 in unprotected regions through the hard mask layer, through the multilayer stack 102, and into the substrate 101, thereby leaving the semiconductor strips 108 and the fins 114. The trenches 116 extend along the X direction. In some embodiments, the semiconductor strips 108 and the fins 114 have a longitudinal axis along the X direction.

The semiconductor device 100 may include a plurality of transistor structures. The first nanostructures 110 or portions thereof may form nanostructure channel(s) of the transistor structures in later fabrication stages, while the second nanostructures 112 may act as sacrificial layers in later fabrication stages for allowing the nanostructure channel(s) to be surrounded by gate structures. The transistor structures having the nanostructure channel(s) may be referred to as nanostructure transistors, nanosheet transistors, nanowire transistors, gate-all-around (GAA) transistors, multi-bridge channel (MBC) transistors, or any transistors having gate electrodes surrounding channels.

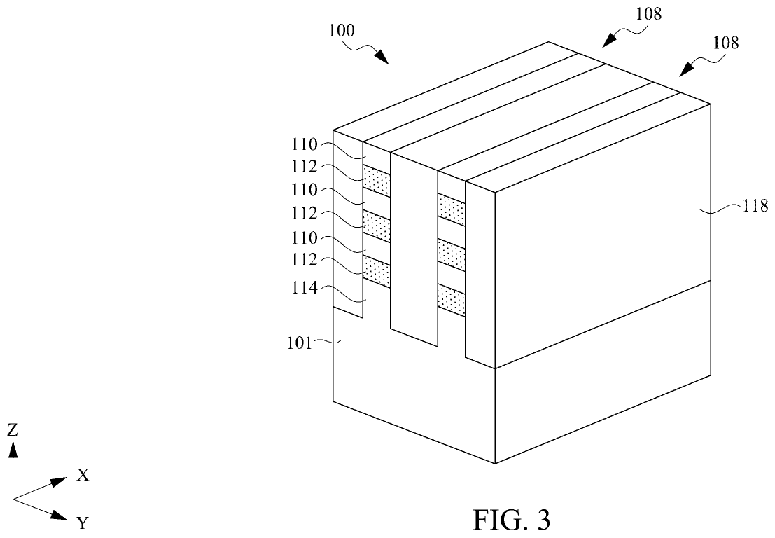

In FIG. 3, after the semiconductor strips 108 are formed, an insulating material 118 is formed over the substrate 101. The insulating material 118 fills the trenches 116 between neighboring semiconductor strips 108 until the semiconductor strips 108 are embedded in the insulating material 118. Then, a planarization operation, such as a chemical mechanical polishing (CMP) method and/or an etch-back method, is performed such that the top of the semiconductor strips 108 is exposed. The insulating material 118 may be made of silicon oxide, silicon nitride, silicon oxynitride (SiON), silicon oxycarbonitride (SiOCN), silicon carbonitride (SiCN), fluorine-doped silicate glass (FSG), a low-K dielectric material (k-value less than about 3.5), or any suitable dielectric material. The insulating material 118 may be formed by any suitable method, such as flowable CVD (FCVD), low-pressure chemical vapor deposition (LPCVD), or plasma-enhanced CVD (PECVD).

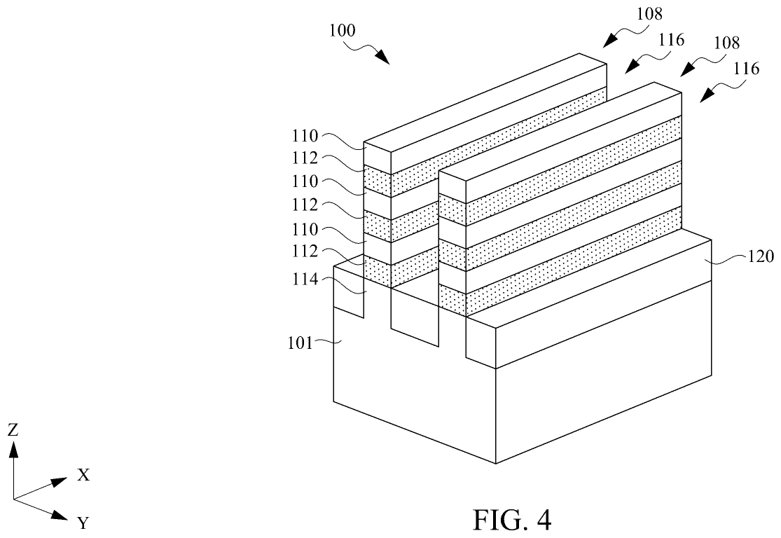

In FIG. 4, the insulating material 118 is recessed to form isolation regions 120. The recess of the insulating material 118 exposes portions of the semiconductor strips 108 and the substrate 101. The recess of the insulating material 118 reveals the trenches 116 between the neighboring semiconductor strips 108. The isolation regions 120 may be formed using a suitable process, such as a dry etch process, a wet etch process, or a combination thereof. Top surfaces of the isolation regions 120 may be level with or below top surfaces of the fins 114 and in contact with the fins 114.

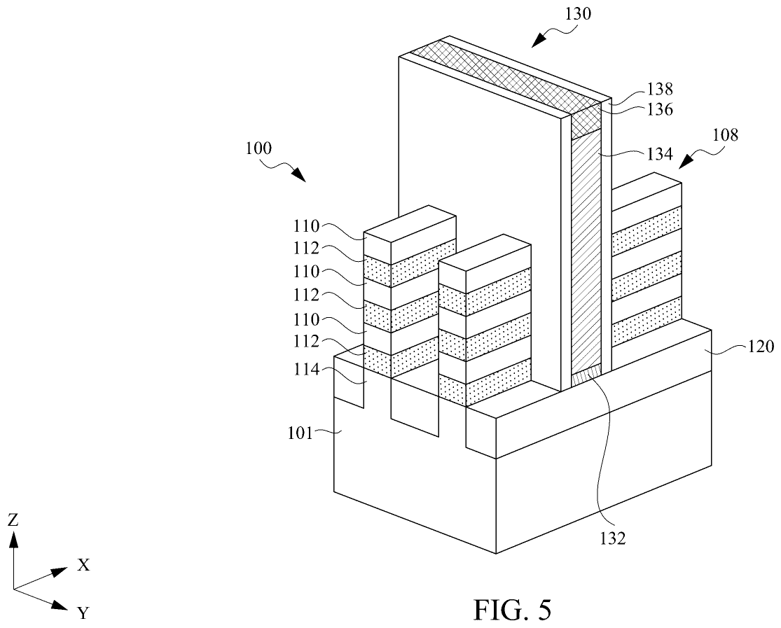

In FIG. 5, one or more dummy gate structures 130 (only one is shown) are formed over the semiconductor device 100. The dummy gate structures 130 are formed over a portion of the semiconductor strips 108. Each dummy gate structure 130 may include a dummy gate dielectric 132, a dummy gate electrode 134, and a hard mask 136. The dummy gate dielectric 132, the dummy gate electrode 134, and the hard mask 136 may be formed by sequentially depositing blanket layers of the dummy gate dielectric 132, the dummy gate electrode 134, and the hard mask 136, and then patterning those layers into the dummy gate structures 130. The dummy gate structure 130 may have a longitudinal direction (e.g., the Y-direction in FIG. 5) substantially perpendicular to the longitudinal directions of the semiconductor strips 108 (e.g., the X-direction in FIG. 5). The dummy gate structure 130 may land on the isolation regions 120 and cross over a single one or a plurality of the semiconductor strips 108.

The dummy gate dielectric 132 may include one or more layers of dielectric material, such as a deposited oxide-based material (e.g., silicon oxide) or a material oxidized from the substrate 101. The dummy gate electrode 134 may include silicon such as polycrystalline silicon or amorphous silicon. The hard mask 136 may include one or more dielectric layers. For example, the hard mask 136 may be a combination of an oxide layer and a nitride layer.

Gate spacers 138 are then formed on sidewalls of the dummy gate structure 130. The gate spacers 138 may be formed by conformally depositing one or more layers for the gate spacers 138 and anisotropically etching (e.g., RIE) the one or more layers. Dielectric materials such as silicon nitride (SiN), silicon oxide (SiO), silicon carbide (SiC), silicon carbonitride (SiCN), silicon oxynitride (SiON), silicon oxycarbonitride (SiOCN), combinations thereof, or the like, may be used for the gate spacers 138.

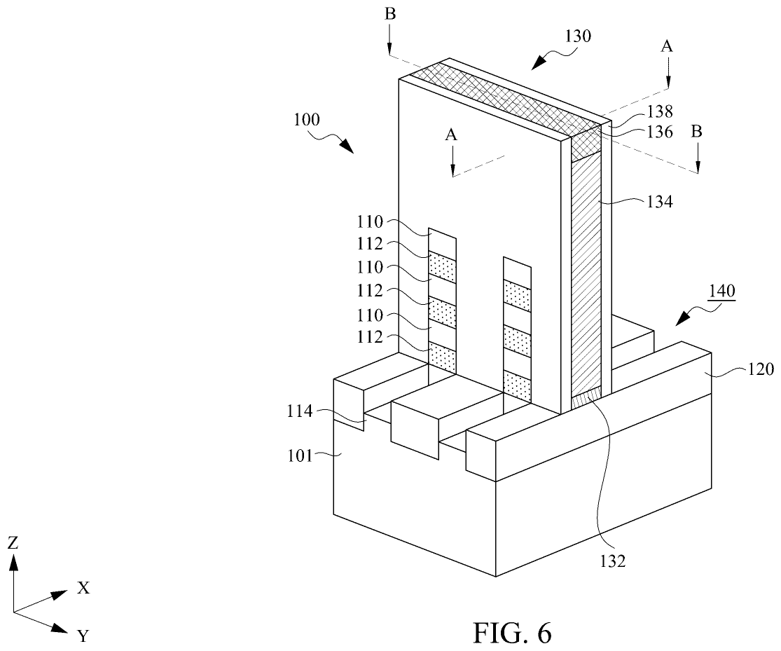

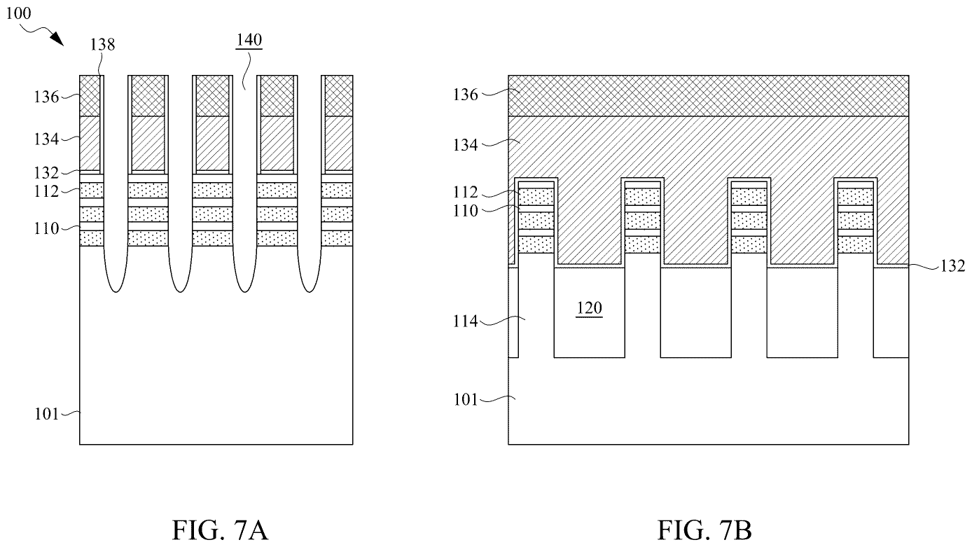

In FIG. 6, first openings 140 are formed in the semiconductor strips 108, the fins 114, and the substrate 101, in accordance with some embodiments. The first openings 140 may be formed by removing at least portions of the semiconductor strips 108 and the substrate 101 that are not protected by the gate spacers 138 and the dummy gate structures 130. As such, the first openings 140 may be formed between neighboring dummy gate structures 130 in the X-direction as illustrated in FIG. 6 (or the cross-sectional view illustrated in FIG. 7). The first openings 140 may be recessed to below the top surfaces of the isolation regions 120, although the first openings also can be recessed to level with or above the top surfaces of the isolation regions 120. The first openings 140 may be formed by an etch process, either isotropic or anisotropic etch process, and the etch process may be selective with respect to one or more crystalline planes of the substrate 101. The etch process may be a dry etch, such as a RIE, NBE, or the like, or a wet etch. The etchant from the etch process may include C₂H₄F₂, C₂F₆, CF₄, with or without a mixture of HBr, Cl₂, O₂, or the like or any suitable etchant.

FIGS. 7A and 7B are cross-sectional views of the semiconductor device 100 taken in directions along cross-section A-A and cross-section B-B of FIG. 6, respectively. A plurality of dummy gate structures 130, a plurality of semiconductor strips 108 and more detail elements are illustrated in the cross-sectional views, in accordance with some embodiments. Throughout the description, the figures with figure numbers including “A” are obtained from the reference cross-section A-A in FIG. 6, and Figure numbers including “B” are obtained from the reference cross-section B-B in FIG. 6.

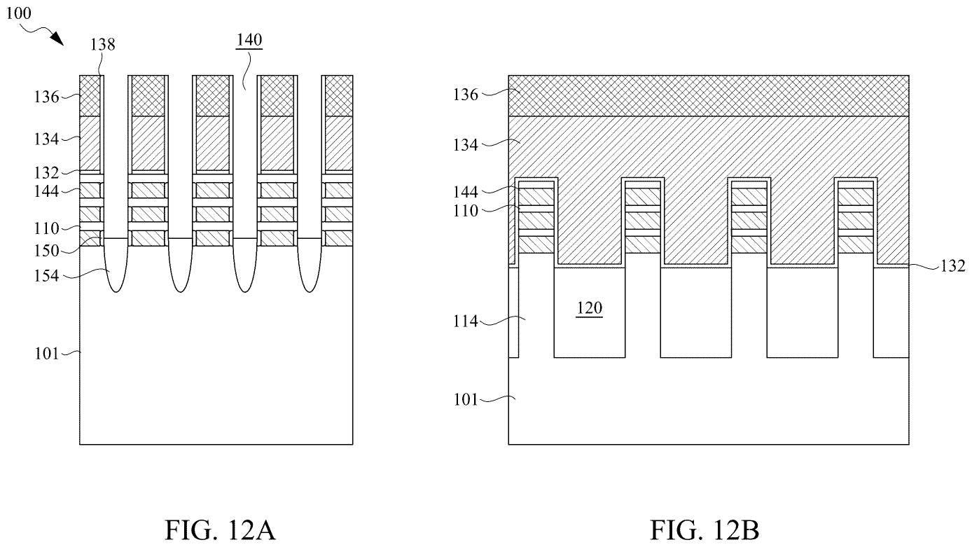

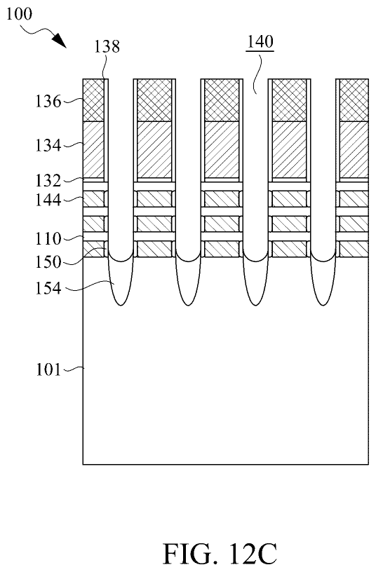

In FIGS. 7A and 7B, the first openings 140 extend through the stack of the first nanostructures 110 and the second nanostructures 112, and into the substrate 101. In some embodiments, the first openings 140 have an extended depth, such as at least about 2 times greater than the height of the stack of the first nanostructures 110 and the second nanostructures 112. The extended depth of the first openings 140 may provide sufficient room for forming isolate filling 154 (FIG. 12A).

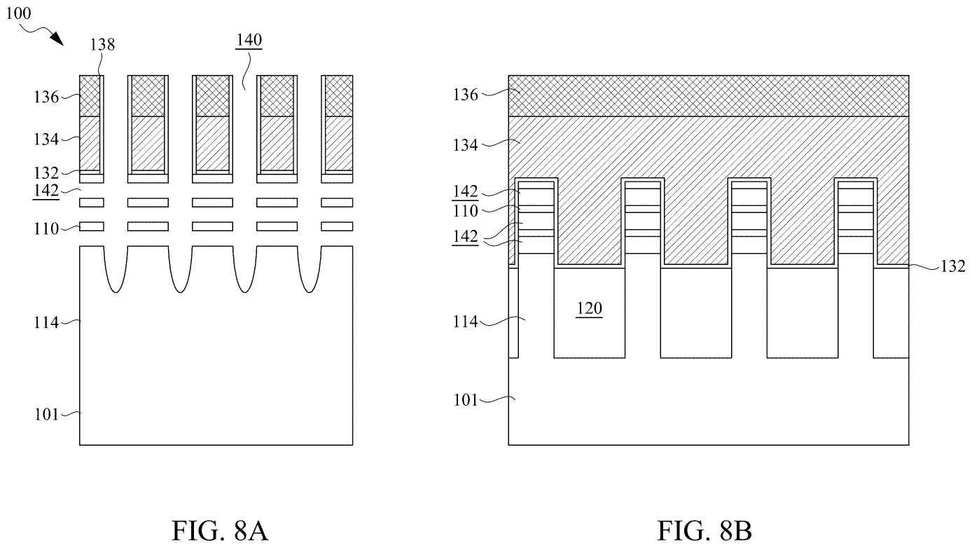

In FIGS. 8A and 8B, the second nanostructures 112 exposed by the first openings 140 are etched to form second openings 142, in accordance with some embodiments. That is, the second openings 142 may be space that was occupied by the second nanostructures 112, including the space between the adjacent first nanostructures 110 and between the bottommost first nanostructure 110 and the substrate 101. While using etchants selective to etch the second semiconductor material of the second nanostructures 112, the first nanostructures 110 and the substrate 101 remain relatively unetched. In an embodiment that the second semiconductor material includes, e.g., SiGe, an etch process using a hydroxide etchant, such as tetramethylammonium hydroxide (TMAH), ammonium hydroxide (NH₄OH), or the like, is used.

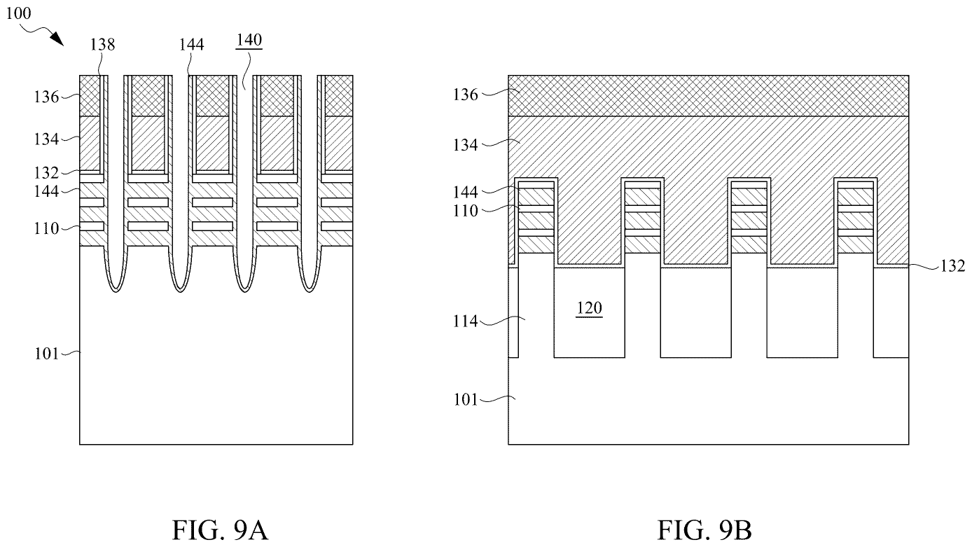

In FIGS. 9A and 9B, an insulating layer 144 is deposited in the first openings 140 and the second openings 142, in accordance with some embodiments. In some embodiments, given the size differences between the first openings 140 and the second openings 142, the insulating layer 144 may substantially or completely fill the second openings 142 and form a conformal layer in the first openings 140. The insulating layer 144 may include an oxide-containing material, such as silicon oxide, silicon oxynitride, SiOCN, SiCN, fluorine-doped silicate glass (FSG), a low-K dielectric material, or any suitable dielectric material. In some embodiments, the insulating layer 144 includes a material similar to those of the isolation regions 120. The insulating layer 144 may be formed by any suitable depositing method, such as FCVD, ALD, PECVD, LPCVD, combinations thereof, or the like.

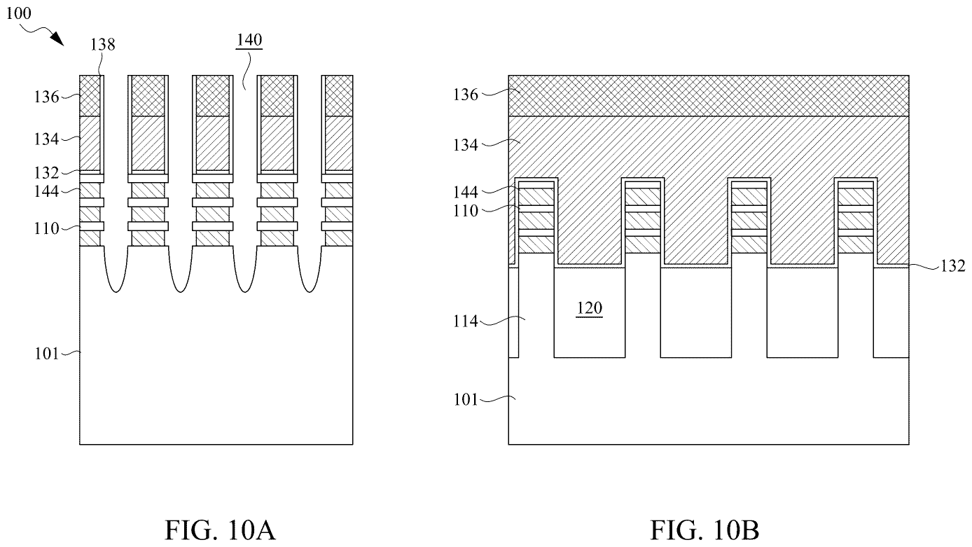

In FIGS. 10A and 10B, an etch process is performed to remove the insulating layer 144 in the first openings 140 and partially recess the insulating layer 144 in the second openings 142 (FIG. 8A), in accordance with some embodiments. The etch process may use etchants selective to etch the insulating layer 144, and the first nanostructures 110 and the substrate 101 may remain relatively unetched. The etch process may be an isotropic etch process. In some embodiments, the isotropic etch process is performed for a sufficient time to remove the insulating layer 144 in the first openings 140 and laterally recess the insulating layer 144 in the second openings 142. Accordingly, the insulating layer 144 is substantially or completely removed in the first openings 140. In an embodiment in which the insulating layer 144 remains in the first openings 140 after the isotropic etch process, a further anisotropic process may be performed to substantially or completely remove the insulating layer 144 in the first openings 140.

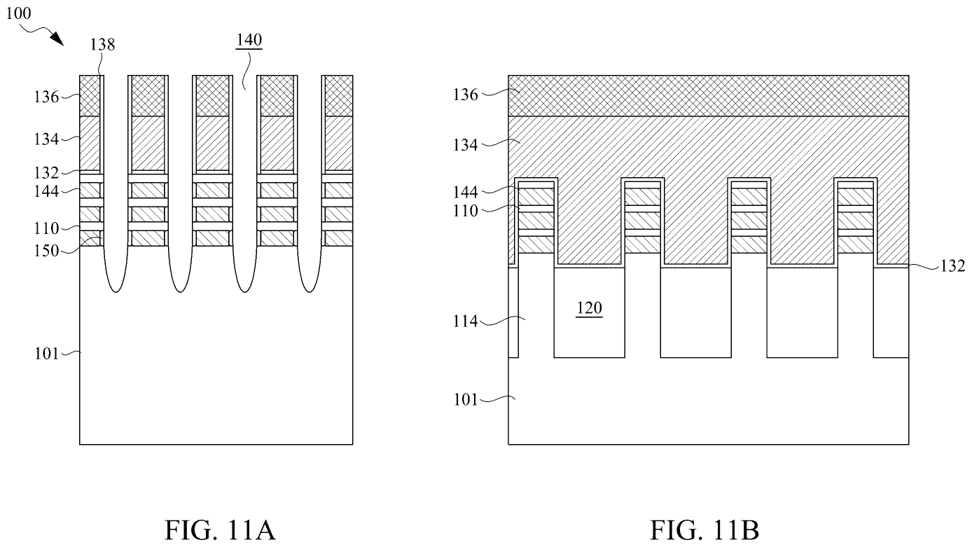

In FIGS. 11A and 11B, inner spacers 150 are formed in the lateral recesses and on the sidewalls of the insulating layer 144, in accordance with some embodiments. The inner spacers 150 may act as isolation features between subsequently formed source/drain regions and a gate structure. As will be discussed in greater detail below, the source/drain regions will be formed in the first openings 140, and the insulating layer 144 will be replaced with gate structures.

In some embodiments, an inner spacer layer is deposited by a conformal deposition process, such as CVD, ALD, or the like. The inner spacer layer may include a material such as silicon nitride or silicon oxynitride, although any suitable material, such as a low-K dielectric material, may be utilized. The inner spacer layer may then be anisotropically etched to form the inner spacers 150, such as by RIE, NBE, or the like, using the gate spacers 138 as a mask. Although outer sidewalls of the inner spacers 150 are illustrated as being flush with sidewalls of the first nanostructures 110 in FIG. 11A, the outer sidewalls of the inner spacers 150 may extend beyond or be recessed from sidewalls of the first nanostructures 110. Moreover, although the outer sidewalls of the inner spacers 150 are illustrated as being straight in FIG. 11A, the outer sidewalls of the inner spacers 150 may be concave or convex.

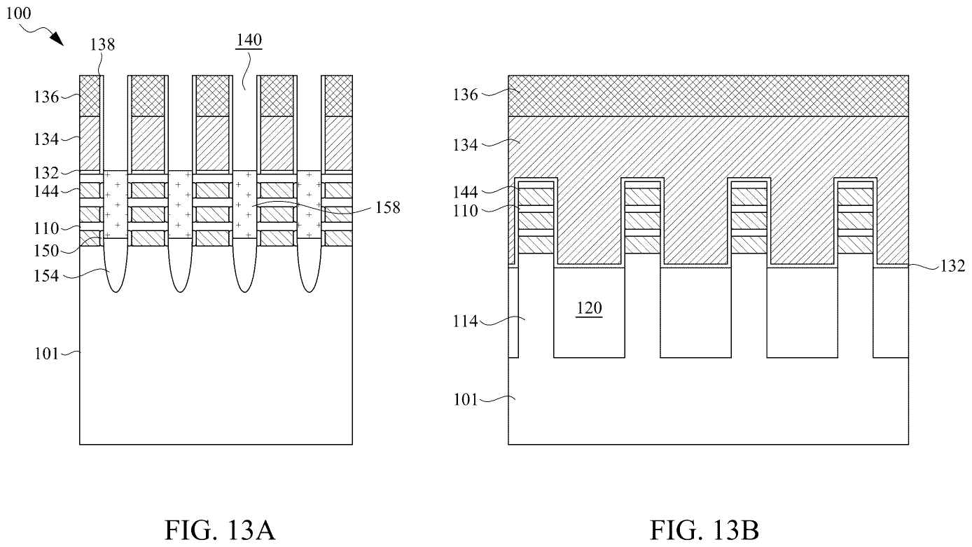

In FIGS. 12A and 12B, an isolate filling 154 is formed in the first openings 140, in accordance with some embodiments. The isolate filling 154 may be formed, for example, by depositing a dielectric layer having a relatively thick thickness on the bottom of the first openings 140 and relatively a thinner thickness on the sidewalls of the first openings 140, and a trimming etch process may then be performed to remove the dielectric layer on the sidewalls of the first openings 140. The deposition of the dielectric layer may include FCVD, PECVD, LPCVD, combinations thereof, or the like. The trimming etch process may be a wet etch, a dry etch with a suitable inclined angle, or a combination thereof. In some embodiments, the processes of depositing the dielectric layer and trimming etch processes may be repeated to allow the isolate filling 154 to have a sufficient thickness at the bottom of the first openings 140. The isolate filling 154 may at least cover the exposed surfaces of the first openings 140 below the bottommost insulating layer 144 to isolate the subsequently formed source/drain regions 158 (FIG. 13A) from the substrate 101. Since the first openings 140 have an extended depth in the substrate 101, the isolate filling 154 also effectively reduces or prevents leakage or cross-talk between adjacent epitaxial source/drain regions (FIG. 13A). In some embodiments, the isolate filling includes a dielectric material, such as silicon oxide, silicon oxynitride, silicon nitride, silicon carbide, silicon oxycarbide, a combination thereof, or the like. In some embodiments, the isolate filling includes SiGe when the epitaxial source/drain regions (FIG. 13A) are not formed of SiGe or include a bottom layer not formed of SiGe.

The upper surface of the isolate filling 154 may be a planar surface, a convex surface, or a concave surface. In some embodiments, as illustrated in FIG. 12C, the upper surface of the isolate filling 154 may be a concave surface to allow more volume of the source/drain regions 158 to be formed in the first openings 140, which may provide improved electrical performance. In some embodiments, the upper surface of the isolate filling 154 may vertically overlap the bottommost inner spacers 150 (e.g., between the bottom of the bottommost first nanostructure 110 and the top of the fin 114/substrate 101). The isolate filling 154 may not be in physical contact with the first nanostructures 110.

In FIGS. 13A and 13B, source/drain regions 158 are formed in the first openings 140 and over the isolate filling 154, in accordance with some embodiments. In this disclosure, a source region and a drain region are interchangeably used, and the structures thereof are substantially the same. Furthermore, source/drain region(s) may refer to a source or a drain, individually or collectively, depending upon the context. The source/drain regions may exert stress on the first nanostructures 110, thereby improving device performance. The source/drain regions 158 may be made of one or more layers of Si, SiP, SiC and SiCP for n-channel FETs or one or more layers of Si, SiGe, Ge for p-channel FETs. For p-type field effect transistors (PFETs), p-type impurities, such as boron, boron fluoride, indium, or the like, may be included in the source/drain regions 158. For n-type field effect transistors (NFETs), n-type impurities, such as phosphorus, arsenic, antimony, or the like, may be included in the source/drain regions 158. The source/drain regions 158 may be formed by an epitaxial growth method using such as, CVD, ALD, MBE, combinations therefore, or the like, and can also be referred to as epitaxial source/drain regions 158. In some embodiments, the impurities may be in situ doped when epitaxially depositing the source/drain regions 158. The source/drain region 158 may have an impurity concentration of between about 1×10¹⁹ atoms/cm³ and about 1×10²¹ atoms/cm³. In some embodiments, the source/drain regions 158 grow to form facets, which may correspond to crystalline planes of the material used for the substrate 101.

In FIGS. 14A and 14B, a contact etch stop layer (CESL) 160 is conformally formed on the exposed surfaces of the semiconductor device 100, in accordance with some embodiments. The CESL 160 covers the isolation regions 120, the source/drain regions 158, and the sidewalls of the gate spacers 138. The CESL 160 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 162 is formed on the CESL 160 over the semiconductor device 100. The materials for the first ILD layer 162 may include compounds including Si, O, C, and/or H, such as silicon oxide, SiCOH, SiOC, PSG, BSG, BPSG, combinations thereof, or the like. Organic materials, such as polymers, may also be used for the first ILD layer 162. The first ILD layer 162 may be deposited by FCVD, PECVD, or other suitable deposition techniques. In some embodiments, after the first ILD layer 162 is deposited, a thermal process is performed to cure the first ILD layer 162. After the first ILD layer 162 is formed, a planarization operation, such as CMP, is performed to level the top surface of the first ILD layer 162 with the top surfaces of dummy gate electrodes 134 or the hard masks 136. In some embodiments in which the hard masks 136 remain, the planarization process levels the top surface of the first ILD layer 162 with the top surfaces of the hard masks 136 and the gate spacers 138. In some embodiments, top surfaces of the dummy gate electrodes 134, the gate spacers 138, and the first ILD layer 162 are level within process variations after the planarization process. In such embodiments, the top surfaces of the dummy gate electrodes 134 are exposed through the first ILD layer 162.

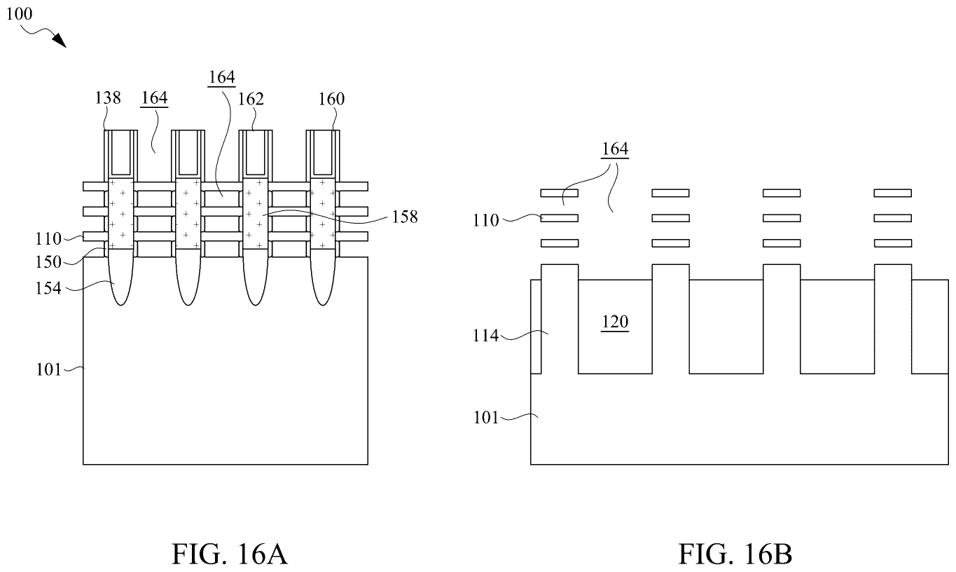

In some embodiments, an optional first capping layer (not shown) is formed over the first ILD layer 162. The formation of the first capping layer may include recessing the first ILD layer 162 between the dummy gate electrodes 134 and filling the recession with the first capping layer created by recessing process. Filling the recession with the first capping layer may be achieved by any suitable deposition process, such as CVD, PECVD, ALD, or other suitable methods. In some embodiments, a planarization process is then performed to remove excess portions of the first capping layer over the dummy gate electrodes 134, so an upper surface of the first capping layer is level with the upper surfaces of the dummy gate electrodes 134 or the hard masks 136 (if exists). In some embodiments, the first capping layer includes silicon nitride, silicon oxynitride, silicon carbide, silicon carbonitride, silicon oxycarbonitride, a combination thereof, or the like. The first capping layer may protect the first ILD layer 162 not being damaged in the process of removing the insulating layer 144 as illustrated in FIGS. 16A and 16B.

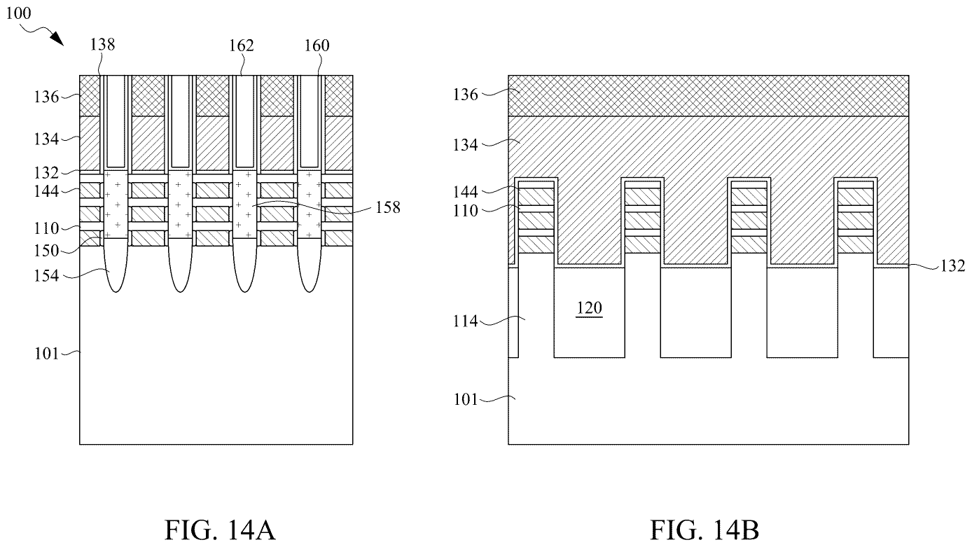

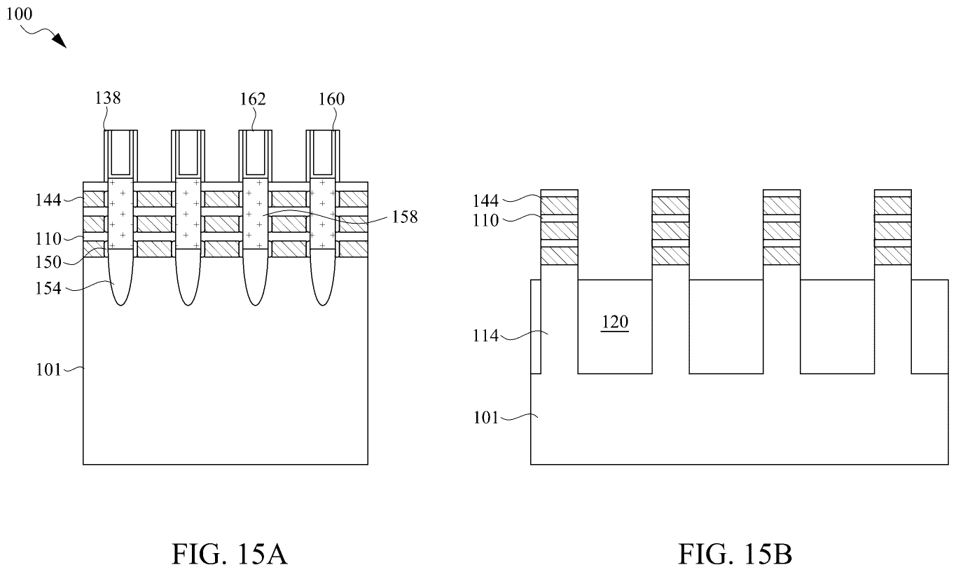

In FIGS. 15A and 15B, the dummy gate electrodes 134 and the hard masks 136 (if exist) are removed. In some embodiments, the dummy gate dielectrics 132 are also removed after the dummy gate electrodes 134 are removed. The hard masks 136, the dummy gate electrodes 134 and the dummy gate dielectrics 132 may be removed by one or more etch processes. For example, an etch process may be performed by etching the hard masks 136 using the dummy gate electrodes 134 as an etch stop, etching the dummy gate electrodes 134 using the dummy gate dielectrics 132 as an etch stop, and the dummy gate dielectrics 132 are then removed by another etch process. In some embodiments, the etch process for etching the dummy gate electrodes 134 and the dummy gate dielectrics 132 may include using reaction gas(es) that selectively etch the dummy gate electrodes 134 and the dummy gate dielectrics 132 at a faster rate than the first ILD layer 162 or the gate spacers 138. As illustrated in FIG. 15B, after the dummy gate dielectrics 132 and the dummy gate electrodes 134 are removed, the insulating layer 144 is exposed.

In FIGS. 16A and 16B, the insulating layer 144 is removed, in accordance with some embodiments. The insulating layer 144 may be removed by an isotropic etch process, such as by a wet etching containing an etchant containing a dilute HF or other suitable etchants. The removal of the hard masks 136, the dummy gate electrodes 134, the dummy gate dielectrics 132, and the insulating layer 144 forms third openings 164 between the gate spacers 138 and between the first nanostructures 110. In some embodiments, the processes related to the insulating layer 144, such as the processes illustrated in FIGS. 8A-11B can be omitted so the second nanostructures 112 still remain and not replaced with the insulating layer 144. In such embodiments, the third openings 164 are formed by removing the second nanostructures 112, and features such as the inner spacers 150 and the isolate filling 154 as illustrated in FIGS. 12A-15B are still formed and located at the positions as shown in FIG. 16A.

In some embodiments, before the insulating layer 144 is removed, an optional second capping layer (not shown) is formed over the isolation regions 120. The formation of the second capping layer may include depositing a dielectric material over the upper surfaces of the isolation regions 120 and exposed surfaces of the first nanostructures 110 and the insulating layer 144. In some embodiments, by adjusting suitable deposition parameters or depending on the deposition methods (e.g., FCVD), a thickness of the dielectric material over the upper surfaces of the isolation regions 120 may be greater than a thickness of the dielectric material over the exposed surfaces of the first nanostructures 110 and the insulating layer 144. An etch process may then be performed to remove the dielectric material of over the exposed surfaces of the first nanostructures 110 and the insulating layer 144 while some of the dielectric material on the upper surfaces of the isolation regions 120 may remain to form the second capping layer. The etch process may include a wet etch process, a dry etch process, or a combination thereof. In some embodiments, the second capping layer includes silicon nitride, silicon oxynitride, silicon carbide, silicon carbonitride, silicon oxycarbonitride, a combination thereof, or the like. The second capping layer may protect the isolation regions 120 not being damaged in the process of removing the insulating layer 144.

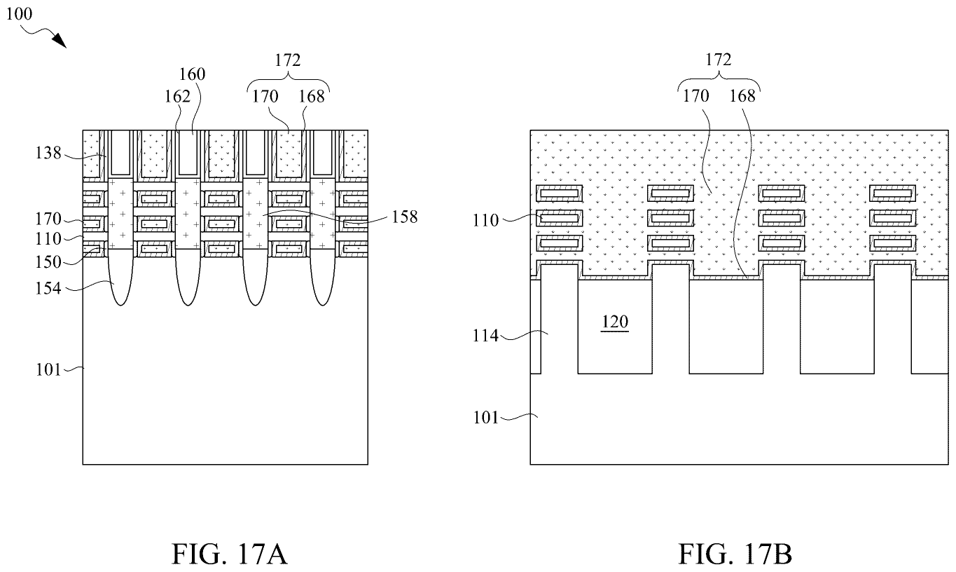

In FIGS. 17A and 17B, gate dielectric layers 168 and gate electrodes 170 are formed for replacement gates. The gate dielectric layers 168 are deposited conformally in the third openings 164. The gate dielectric layers 168 may be formed on top surfaces and sidewalls of the substrate 101 and on exposed surfaces of the first nanostructures 110, In some embodiments, the gate dielectric layers 168 are also deposited on top surfaces of the first ILD layer 162, the CESL 160, the gate spacers 138, and the isolation regions 120. In some embodiments, the gate dielectric layers 168 include one or more layers of a dielectric material, such as silicon oxide, silicon nitride, or high-K dielectric material, other suitable dielectric material, and/or combinations thereof. Examples of high-K dielectric material include HfO, HfSiO, HfSiON, HfTaO, HfTiO, HfZrO, zirconium oxide, aluminum oxide, titanium oxide, hafnium oxide-alumina (HfO—AlO) alloy, other suitable high-K dielectric materials, and/or combinations thereof. The gate dielectric layers 168 may be formed by CVD, ALD, or any suitable deposition techniques.

The gate electrodes 170 are deposited over the gate dielectric layer 168, respectively, and fill the remaining portions of the third openings 164. The gate electrodes 170 may include a metal-containing material such as titanium nitride, titanium oxide, tantalum nitride, tantalum carbide, cobalt, ruthenium, aluminum, tungsten, combinations thereof, or multi-layers thereof. Although single-layer gate electrodes 170 are illustrated in FIGS. 17A and 17B, the gate electrodes 170 may comprise any number of liner layers, any number of work function tuning layers, and a fill material. The gate electrodes 170 may be formed by CVD, ALD, electro-plating, or other suitable deposition techniques. After filling the third openings 164, excess materials of the gate dielectric layers 168 and the gate electrodes 170 over the top surface of the first ILD layer 162 are then removed by a planarization process, such as CMP, until the top surfaces of the first ILD layer 162 are exposed. The remaining portions of the gate electrodes 170 and the gate dielectric layers 168 thus form replacement gate structures of the semiconductor device 100. The gate electrodes 170 and the gate dielectric layers 168 may be collectively referred to as gate structures 172. The gate structures 172 may surround channels (i.e., the first nanostructures 110) of the semiconductor device 100.

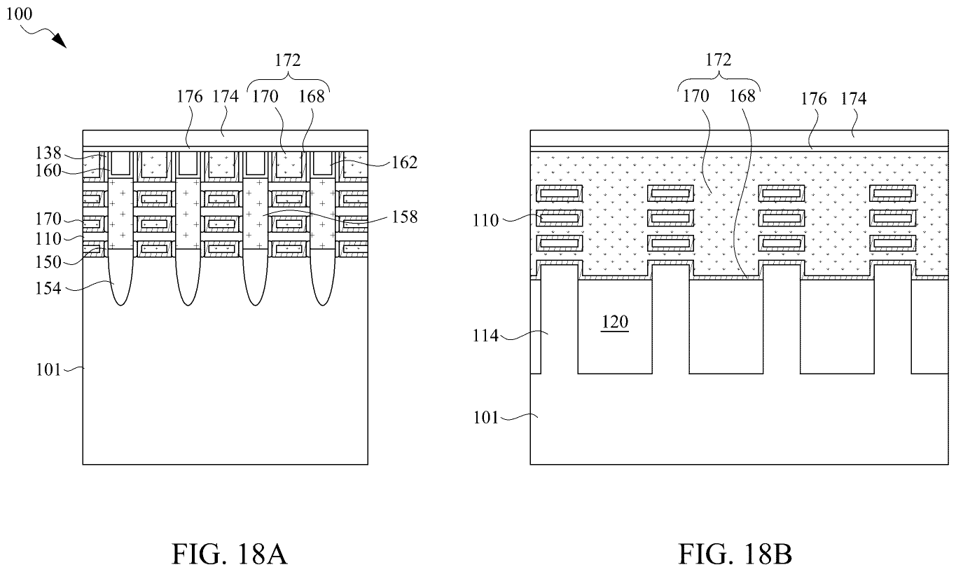

As further illustrated by FIGS. 18A and 18B, a second ILD layer 174 is deposited over the first ILD layer 162. In some embodiments, the second ILD layer 174 is formed of a dielectric material similar to those of the first ILD layer 162 and is formed by a method similar to those used for the first ILD layer 162. In some embodiments, a CESL 176 is also formed before forming the second ILD layer 174. The CESL 176 may include a material similar to those of the CESL 160 and may be formed using methods similar to those used for the CESL 160.

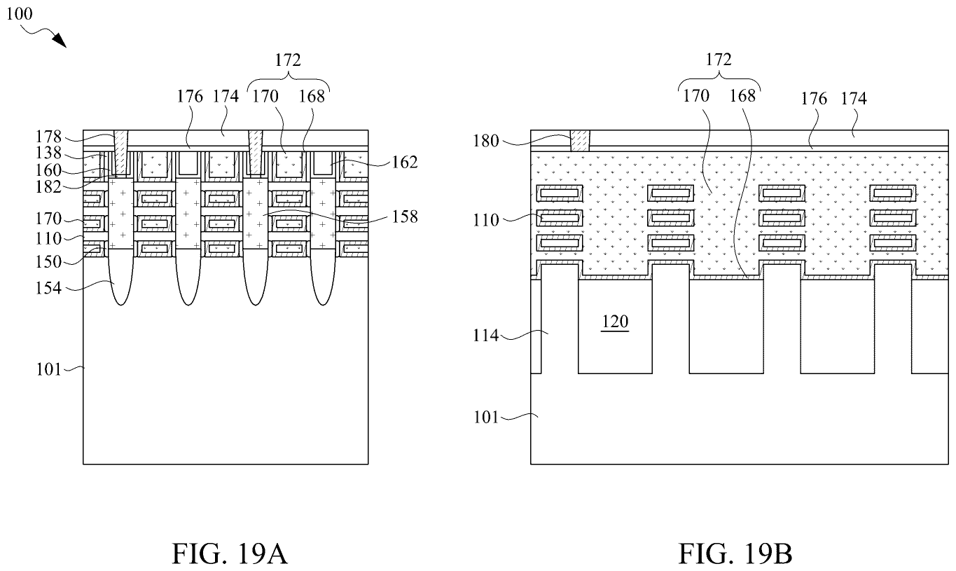

In FIGS. 19A and 19B, contacts 178 and contacts 180 are formed in the first ILD layer 162 and the second ILD layer 174, in accordance with some embodiments. The contacts 178 are electrically coupled to the source/drain regions 158 and may be referred to as source/drain contacts. Because the contacts 178 are formed over the frontside 101F of the substrate 101, the contacts 178 may also be referred to as frontside contacts or frontside source/drain contacts. The contacts 180 are electrically coupled to the gate structures 172 and may be referred to as gate contacts.

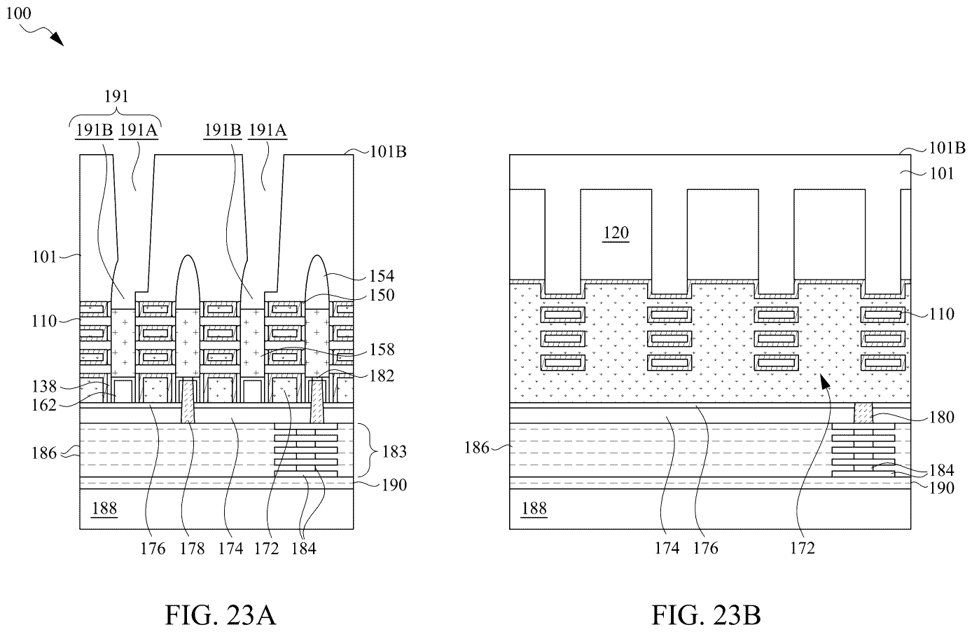

In some embodiments, the contacts 178 are electrically coupled to the source/drain regions 158. For example, the contact 178 may extend to physically connect to frontside of the source/drain regions 158. The contacts 178 are formed over and electrically coupled to some of the source/drain regions 158, and top surfaces of other source/drain regions 158 are completely covered by the CESL 160 and/or the first ILD layer 162. According to design requirements, not all the source/drain regions 158 are electrically coupled to the contacts 178. For example, depending on the design requirements, only some of the source/drain regions 158 are electrically coupled to the contacts 178, and as will be discussed in detail below, some of the source/drain regions 158 may be electrically coupled to backside contacts 192 (FIG. 23A).

In some embodiments, the formation of the contacts 178 and the contacts 180 includes etching the second ILD layer 174, the first ILD layer 96, the CESL 176, and/or the CESL 160 to form recesses exposing surfaces of the source/drain regions 158 and/or the gate structure 172, and the materials of the contacts 178 and 180 are then deposited in the recesses, in accordance with some embodiments. The recesses may be formed by etching using one or more anisotropic etch processes, such as RIE, NBE, or the like.

The contacts 178 and 180 may each comprise one or more layers, such as including a barrier layer (not shown), an adhesive layer (not shown), and a filling material over the barrier layer and/or the adhesive layer. In some embodiments, the barrier layer of the contacts 178 and 180 includes the titanium, titanium nitride, tantalum, tantalum nitride, or the like. The conductive material of the contacts 178 and 180 may be copper, a copper alloy, silver, gold, tungsten, cobalt, aluminum, nickel, or the like. In some embodiments, the contacts 178 also include silicide regions 182 in contact with the source/drain regions 158 to reduce resistance. The silicide regions 182 may be formed between the barrier layer (or the filling material) and the source/drain regions 158 by reacting the materials of the barrier layer (or the filling material) of the contacts 178 with the semiconductor materials of source/drain regions 158. Although silicide regions 182 are referred to as silicide regions, the silicide regions 182 may also be germanide regions, or germano-silcide regions. A planarization process, such as a CMP, may be performed to remove excess materials of the contacts 178 and 180 over the top surface of the second ILD layer 174.

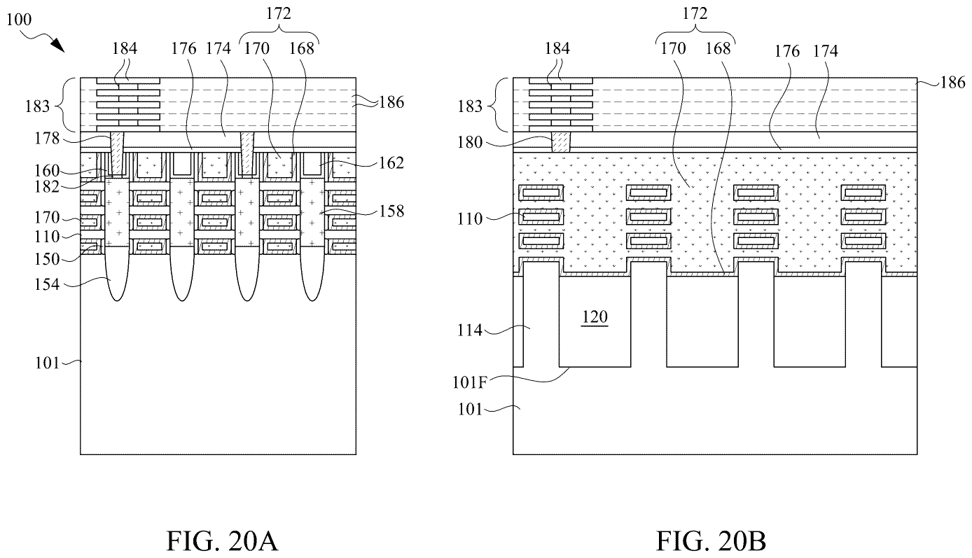

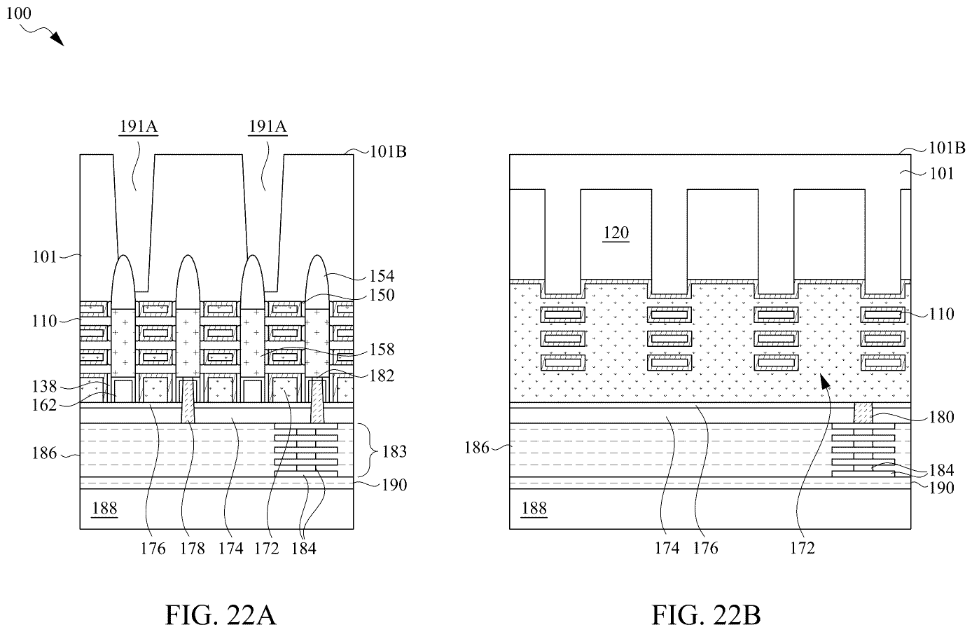

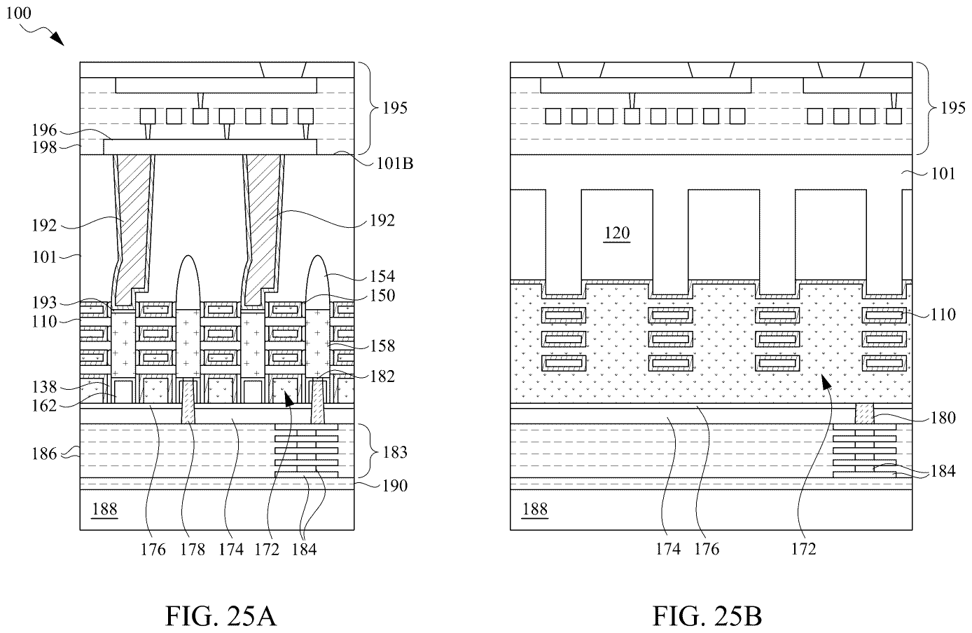

FIGS. 20A-25B illustrate intermediate steps of forming a frontside interconnect structure 183 over the frontside 101F of the substrate 101 (illustrated in FIGS. 20A and 20B), backside contacts 192 in the substrate 101 (illustrated in FIGS. 22A-24B), and a backside interconnect structure 195 over the backside 101B of the substrate 101 (illustrated in FIGS. 25A and 25B), in accordance with some embodiments. In FIGS. 20A and 20B, the frontside interconnect structure 183 is formed over the frontside 101F of the substrate 101, such as over the second ILD layer 174, in accordance with some embodiments. The frontside interconnect structure 183 may comprise one or more layers of conductive features 184 formed in one or more stacked dielectric layers 186. Each of the stacked dielectric layers 186 may comprise a dielectric material, such as silicon oxide, PSG, BSG, BPSG, a low-K dielectric material, combinations thereof, or the like. The dielectric layers 186 may be deposited using an appropriate process, such as CVD, PECVD, PVD, or the like.

The conductive features 184 may comprise conductive lines and conductive vias interconnecting the layers of conductive lines. The conductive vias may extend through respective ones of the dielectric layers 186 to provide vertical connections between layers of the conductive lines. The conductive features 184 may be formed through any acceptable process, such as, a single damascene process, a dual damascene process, a combination thereof, or the like. For example, the conductive features 184 may be formed using a damascene process in which a respective dielectric layer 186 is patterned utilizing a combination of photolithography and etching techniques to form trenches corresponding to the desired pattern of the conductive features 184. An optional diffusion barrier and/or optional adhesion layer may be deposited and the trenches may then be filled with a conductive material. Suitable materials for the barrier layer include titanium, titanium nitride, titanium oxide, tantalum, tantalum nitride, titanium oxide, combinations thereof, or the like, and suitable materials for the conductive material include copper, silver, gold, tungsten, aluminum, combinations thereof, or the like. In an embodiment, the conductive features 184 may be formed by depositing a seed layer of copper or a copper alloy and filling the trenches by electroplating. A chemical mechanical planarization (CMP) process or the like may be used to remove excess conductive material from a surface of the respective dielectric layer 186 and to planarize surfaces of the dielectric layer 186 and the conductive features 184 for subsequent processing.

FIGS. 20A and 20B illustrate five layers of the conductive features 184 and the dielectric layers 186 in the frontside interconnect structure 183. However, it should be appreciated that the frontside interconnect structure 183 may comprise any number of conductive features 184 disposed in any number of dielectric layers 186. The frontside interconnect structure 183 may be electrically connected to the source/drain contacts 178 and the gate contacts 180. In some embodiments, the frontside interconnect structure 183 also includes bump pads at the top layer of the frontside interconnect structure 183 for external connections. The external connections may be electrically coupled to the source/drain regions 158 through the frontside interconnect structure 183 and the contacts 178.

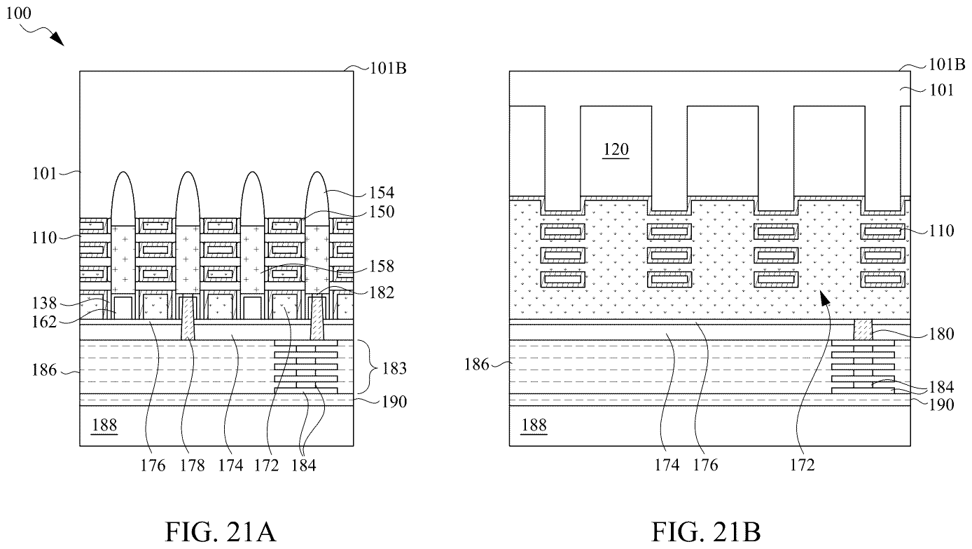

In FIGS. 21A and 21B, a carrier substrate 188 is bonded to a top surface of the frontside interconnect structure 183 through a bonding layer 190. The carrier substrate 188 may be a glass carrier substrate, a ceramic carrier substrate, a wafer (e.g., a silicon wafer), or the like. The carrier substrate 188 may provide structural support during subsequent processing steps and in the completed device.

In some embodiments, the bonding layer 190 may be a thermal-release material, which loses its adhesive property when heated, such as a light-to-heat-conversion (LTHC) release coating; an ultra-violet (UV) glue, which loses its adhesive property when exposed to UV lights; or the like. The bonding layer 190 may be dispensed as a liquid and cured. After the carrier substrate 188 is bonded to the frontside interconnect structure 183, the semiconductor device 100 may be flipped such that the backside 101B of the substrate 101 faces upwards. A thinning process is then applied to the backside 101B of the substrate 101, in accordance with some embodiments. The thinning process may include a planarization process (e.g., a mechanical grinding, a CMP, or the like), an etch-back process, a combination thereof, or the like.

In FIGS. 22A and 22B, openings 191A for the backside contacts 192 are formed in the substrate 101, in accordance with some embodiments. The openings 191A may at least expose a portion of the isolate filling 154. The openings 191A may be formed by a suitable etch process. In some embodiments, the openings 191A may be one or more anisotropic etch processes, such as RIE, NBE, or the like. In some embodiments, the etch processes for the openings 191A may use the isolate filling 154 as a buffer or etch stop so that the openings 191A may not directly extend through the substrate 101. In some embodiments, the etch processes for the openings 191A may also include a time-mode etch to prevent from the openings 191 extending through the substrate 101. The etch processes for the openings 191A may use an etchant that is highly selective to the substrate 101, such as a mixture of Cl₂ or HBr with O₂ or CO₂, or the like. As such, the isolate filling 154 and other elements of the semiconductor device 100 would not be substantially affected while forming the openings 191A in the substrate 101.

In some embodiments, due to process variations, such as lithography resolution limits or overlay shifts, the openings 191A are partially misaligned from the source/drain regions 158. For example, the bottom of the openings 191A may overlap the gate structure 172 in a plan view and will expose the gate structure 172 if extending the openings 191A through the substrate 101. Because the openings 191A are controlled to not extend through the substrate 101, the etch processes for the openings 191A would not damage the gate structure 172. In some embodiments, the thicker the isolate filling 154 may provide a better buffer or etch stop function for the etch processes for forming the openings 191A.

In FIGS. 23A and 23B, openings 191B for the backside contacts 192 are formed by removing the isolate filling 154, in accordance with some embodiments. The openings 191B may be formed by a suitable etch process. In some embodiments, the openings 191B may be one or more isotropic etch processes, such as a wet etch. The etch process for the openings 191B may use an etchant highly selective to the isolate filling 154. For example, the etchant may include HF, a mixture of NH₃ and HF, a combination thereof, or the like, when the isolate filling 154 is or includes an oxide. Alternatively, the etchant may include phosphoric acid, a mixture of HF or NF₃ with H₂ and/or O₂, or the like, when the isolate filling 154 is or includes a nitride. In some embodiments, when isolate filling 154 includes SiGe, the etchant includes a halogen-based gas, such as a mixture selected from NF₃, F₂, HF and CClF₃, with or without being applied with a plasma that can enhance the dissociation of the etchant. When HF and F₂ are used for etching SiGe, a higher etching rate for Si than Ge can be achieved by increasing the ratio of F₂ to HF (e.g., the F₂/HF ration can be in a range of 0.01 to 100). In some embodiments, the dry etch process includes using a plasma to dissociate the etchant. As such, the substrate 101 or other elements of the semiconductor device 100 would not be substantially affected while forming the openings 191B. The openings 191A and 191B together form the openings 191 for the backside contacts 192.

The high etching selectivity between the isolate filling 154 and the substrate 101 makes the openings 191B be formed according to the shapes of the isolate filling 154. Thus, the openings 191B may be directed to the source/drain region 158 in a self-aligned manner, although the openings 191A may be misaligned from the source/drain region 158. With the openings 191 for the backside contacts 192 can be formed to expose the source/drain regions 158 in a self-aligned manner, the risks of damaging the gate structures 172 or forming shorts between the backside contacts 192 and the gate structures 172 can be effectively reduced or prevented. The manufacturing yields and device reliability can be improved.

In FIGS. 23A and 23B, backside contacts 192 are formed in the openings 191, in accordance with some embodiments. In some embodiments, the first nanostructures 110, the source/drain regions 158, the frontside contacts 178, and the backside contacts 192 form transistor structures 100A. In an exemplary embodiment, one transistor structure 100A includes first nanostructures 110 disposed between source/drain region 158A and source/drain region 158B as channels, one frontside contact 178 disposed electrically coupled to the source/drain region 158A, and one backside contact 192 electrically coupled to another source/drain region 158B. The configurations of the contacts 178 and 192 may also be varied according to the design requirement.

In an embodiment, the backside contact 192 includes a first sidewall 192A, a second sidewall 192B, a third sidewall 192C, and a fourth sidewall 192D. The first sidewall 192A may extend from the backside 101B of the substrate 101. In some embodiments, the first sidewall 192A is a straight sidewall and extends in the first direction. The second sidewall 192B may extend from the first sidewall 192A to the source/drain region 158. The second sidewall 192B may not extend in the first direction. In some embodiments, the second sidewall 192B is a curved sidewall or a straight sidewall. As illustrated in FIG. 23A, in the transistor structure 100A, the second sidewall 192B is horizontally more distant away from another source/drain region 158B along a vertical direction toward the source/drain region 158A. The third sidewall 192C may extend from the backside 101B of the substrate 101. In some embodiments, the third sidewall 192C is a straight sidewall and extends in a second direction. For example, the first sidewall 192A and the third sidewall 192C may be sidewalls of the openings 191A and opposite to each other. The fourth sidewall 192D is between the third sidewall 192C and the source/drain region 158A. The fourth sidewall 192D may not extend in the second direction. The fourth sidewall 192D may be a curved sidewall or a straight sidewall. The fourth sidewall 192D may be horizontally closer to another source/drain region 158B along a vertical direction toward the source/drain region 158A. In some embodiments, the third sidewall 192C is longer than the first sidewall 192A. In some embodiments, the second sidewall 192B is longer than the fourth sidewall 192D.

The backside contact 192 may also include a first bottom 192E connecting the second sidewall 192B and the fourth sidewall 192D. In some embodiments, the backside contact 192 also includes a second bottom 192F connecting the third sidewall 192C and the fourth sidewall 192D. The first bottom 192E and the second bottom 192F may extend in any direction, such as a horizontal direction illustrated in FIG. 23A or a non-horizontal direction. In an embodiment, the backside contact 192 extends into the source/drain region 158, and the first bottom 192E has a curved shape. In some embodiments, the second bottom 192F has a straight shape or a curved shape, depending on the etch profiles for forming the openings 191A.

In some embodiments, the backside contacts 192 each include one or more layers, such as a barrier layer 1921 and a filling material 1922 over the barrier layer 1921. In some embodiments, the barrier layer 1921 of the backside contacts 192 includes titanium, titanium nitride, tantalum, tantalum nitride, or the like. The filling material 1922 of the backside contacts 192 may be copper, a copper alloy, silver, gold, tungsten, cobalt, aluminum, nickel, or the like. In some embodiments, the backside contacts 192 also include silicide regions 193 in contact with the source/drain regions 158 to reduce resistance. The silicide regions 193 may be formed between the barrier layer and the source/drain regions 158 by reacting the materials of the backside contacts 192 with the semiconductor materials of source/drain regions 158. A planarization process, such as a CMP, may be performed to remove excess materials of the backside contacts 192 over the backside 101B of the substrate 101.

In FIGS. 25A and 25B, a backside interconnect structure 195 is formed over the backside 101B of the substrate 101 and the exposed surfaces of the backside contacts 192, in accordance with some embodiments. The backside interconnect structure 195 may include conductive features and dielectric layers similar to the frontside interconnect structure 183. For example, the backside interconnect structure 195 may include conductive features 196 stacked in the dielectric layers 198. The backside interconnect structures 195 are formed by methods similar to those of the frontside interconnect structures 183. For example, forming the conductive features 196 may include patterning recesses in the dielectric layer 198 using a combination of photolithography and etch processes, for example. A pattern of the recesses in the dielectric layer 198 may correspond to a pattern of the conductive features 196. The conductive features 196 are then formed by depositing a conductive material in the recesses. In some embodiments, the conductive features 196 comprise a metal layer, which may be a single layer or a composite layer comprising a plurality of sub-layers formed of different materials. In some embodiments, the conductive features 196 comprise copper, aluminum, cobalt, tungsten, titanium, tantalum, ruthenium, or the like. An optional diffusion barrier and/or optional adhesion layer may be deposited prior to filling the recesses with the conductive material. Suitable materials for the barrier layer/adhesion layer include titanium, titanium nitride, titanium oxide, tantalum, tantalum nitride, titanium oxide, or the like. The conductive features 196 may be formed using, for example, CVD, ALD, PVD, plating, or the like. The conductive features 196 are electrically coupled to the source/drain regions 158 through the backside contacts 192.

In some embodiments, the conductive features 196 include power rails, which are conductive lines that electrically connect the source/drain regions 158 to a reference voltage, a supply voltage, or the like. By placing power rails on the backside of the semiconductor device rather than on the front side of the semiconductor die, advantages may be achieved. For example, a gate density of the semiconductor device 100 and/or an interconnect density of the frontside interconnect structure 183 may be increased. Further, the backside of the semiconductor device 100 may accommodate wider power rails, reducing resistance and increasing the efficiency of power delivery to the semiconductor device 100. For example, a width of the conductive features 196 may be at least twice a width of the first level of conductive lines of the frontside interconnect structure 183.

In some embodiments, the backside interconnect structure 195 further includes bump pads at its top layer for external connections. The bump pads for external connections may also be referred to as backside input/output pads that may provide signal, supply voltage, and/or ground connections to the nanostructure transistors. The backside interconnect structures 195 may include one or more embedded passive devices (not shown), such as resistors, capacitors, inductors, or the like. The embedded passive devices may be integrated with the conductive features 196 (e.g., the power rail) to provide circuits (e.g., power circuits) in the backside interconnect structure 195.

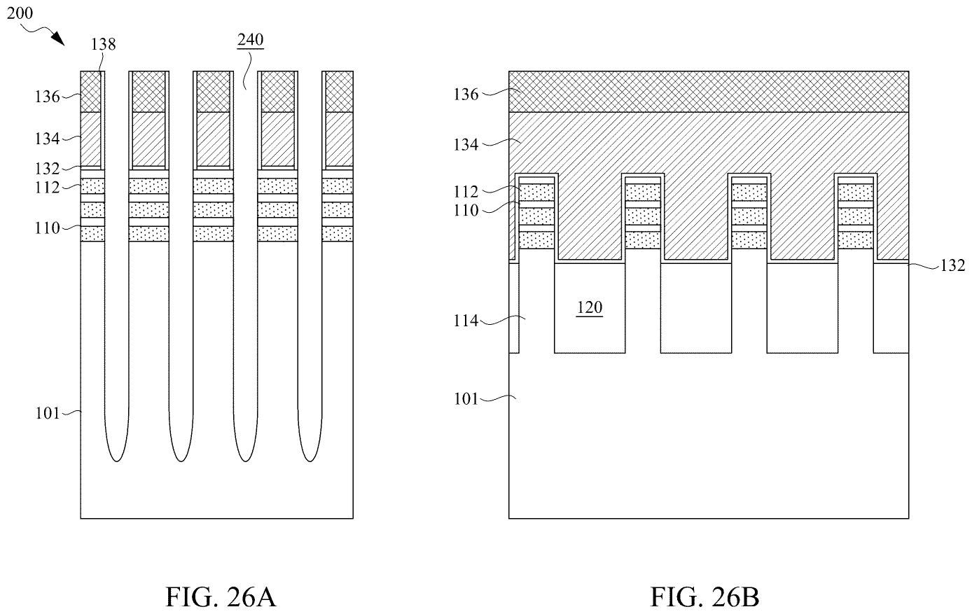

FIGS. 26A-29B illustrate cross-sectional views of intermediate steps in manufacturing a semiconductor device 200, in accordance with some embodiments. The semiconductor device 200 is similar to the semiconductor device 100 and can include any suitable features of the semiconductor device 100, wherein the like reference numeral refers to a like element. In the semiconductor device 200, an isolate filling 254 extending through the substrate 101 is formed to reduce the risks of damaging the gate structure 172 and having shorts between backside contacts and gate structure. Processing of manufacturing the semiconductor device 200 illustrated in FIGS. 26A and 26B assumes the processing illustrated in FIG. 5 performed prior. Accordingly, after the processing discussed above with reference to FIGS. 1-5, processing may proceed to FIGS. 26A and 26B.

In FIGS. 26A and 26B, first openings 240 may be formed with an extended depth, such as at least about 3 times greater than the height of the stack of the first nanostructures 110 and the second nanostructures 112. In some embodiments, the first openings 240 have a depth of about 250 nm to about 350 nm.

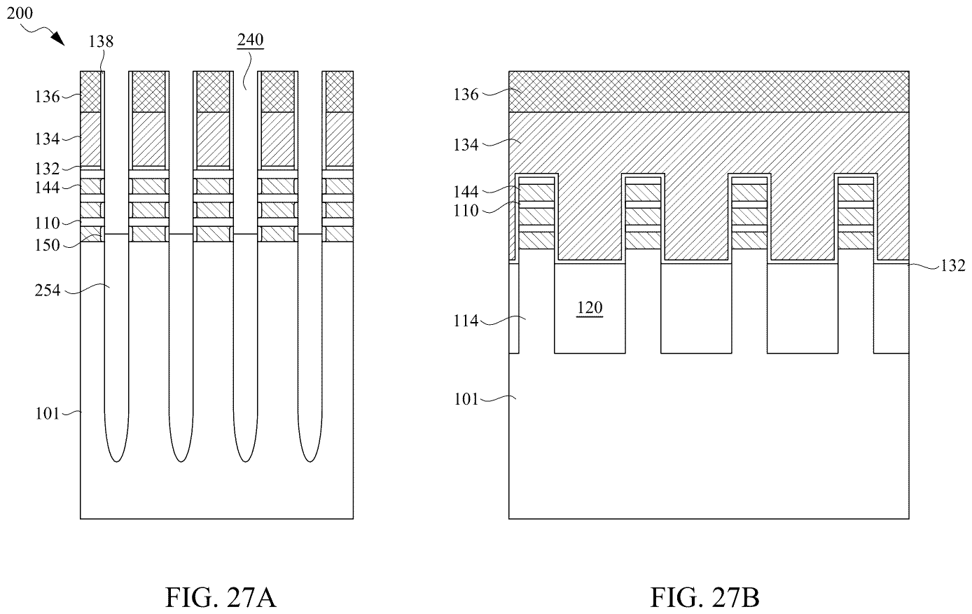

The processes of manufacturing the semiconductor device 200 with reference to FIGS. 8A-11B may then be performed, and processing may proceed to FIGS. 27A and 27B. In FIGS. 27A and 27B, an isolate filling 254 is formed in the first openings 240, in accordance with some embodiments. In an embodiment, the isolate filling 254 has a top surface vertically overlapping with bottommost inner spacer 150. In some embodiments, the isolate filling 254 includes a material similar to those of the isolate filling 154 and may be formed by processes similar to those of forming the isolate filling 154. The top surface of the isolate filling 254 may be planar, concave, or convex.

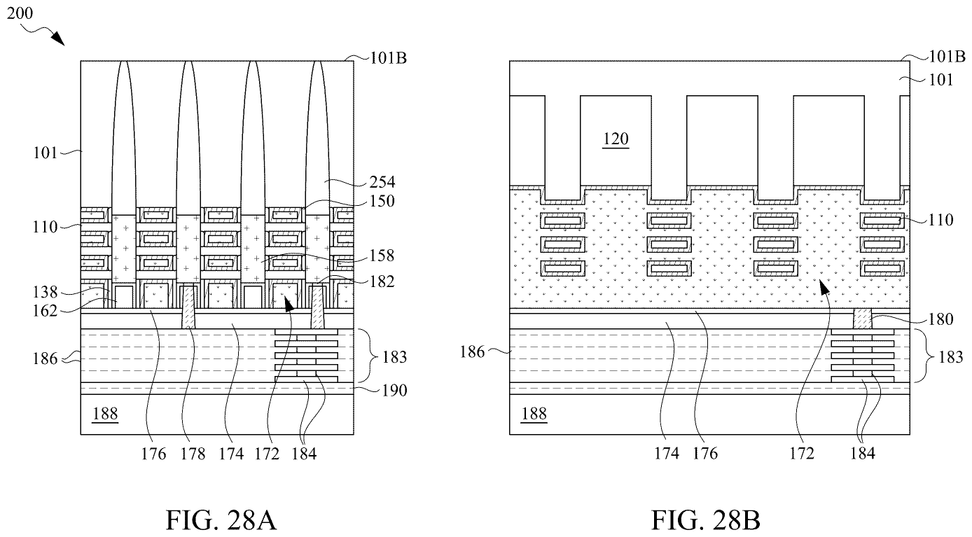

The processes of manufacturing the semiconductor device 200 with reference to FIGS. 13A-20B may then be performed, and processing may proceed to FIGS. 28A and 28B. In FIGS. 28A and 28B, the substrate 101 is thinned from the backside 101B of the substrate 101, and the isolate filling 254 is exposed, in accordance with some embodiments. In an embodiment, a portion of the isolate filling 254 is also removed in the thinning process. The exposed surface of the isolate filling 254 may be coplanar with the backside 101B of the substrate 101.

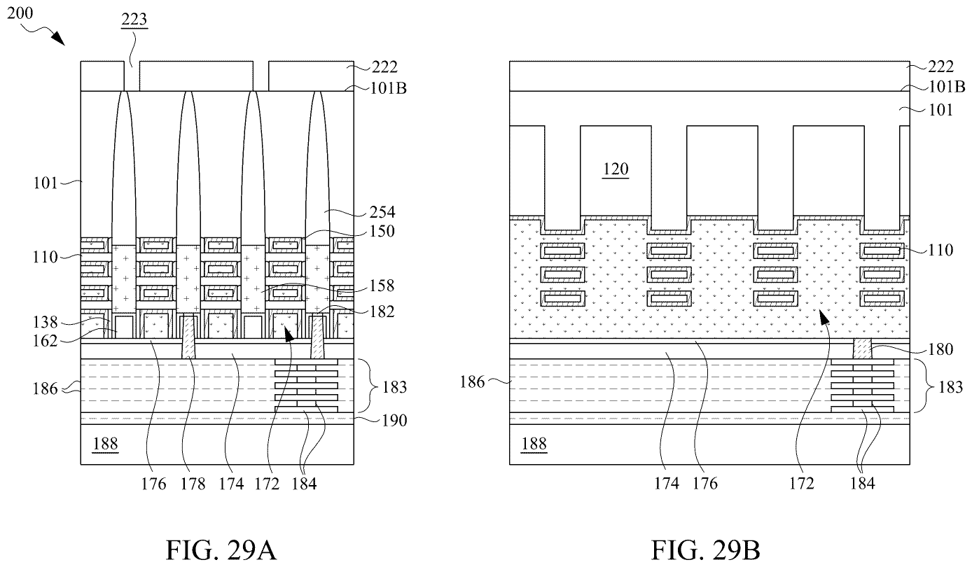

In FIGS. 29A and 29B, a hard mask 222 is formed over the backside 101B of the substrate 101 and the isolate filling 254, and openings 223 exposing the isolate filling 254 are formed in the hard mask 222, in accordance with some embodiments. The hard mask 222 may include silicon oxide, silicon nitride, silicon oxynitride, silicon carbide, silicon carbon nitride, other suitable mask material, a combination thereof, or the like. The hard mask 222 may protect the substrate 101 from being damaged by the subsequent etching processes for forming backside contacts. The openings 223 may be formed in the hard masks 222 using one or more suitable lithography and etch processes. As such, the openings 223 may be laterally misaligned with source/drain regions 158 due to lithography resolution limit or overlay shifts.

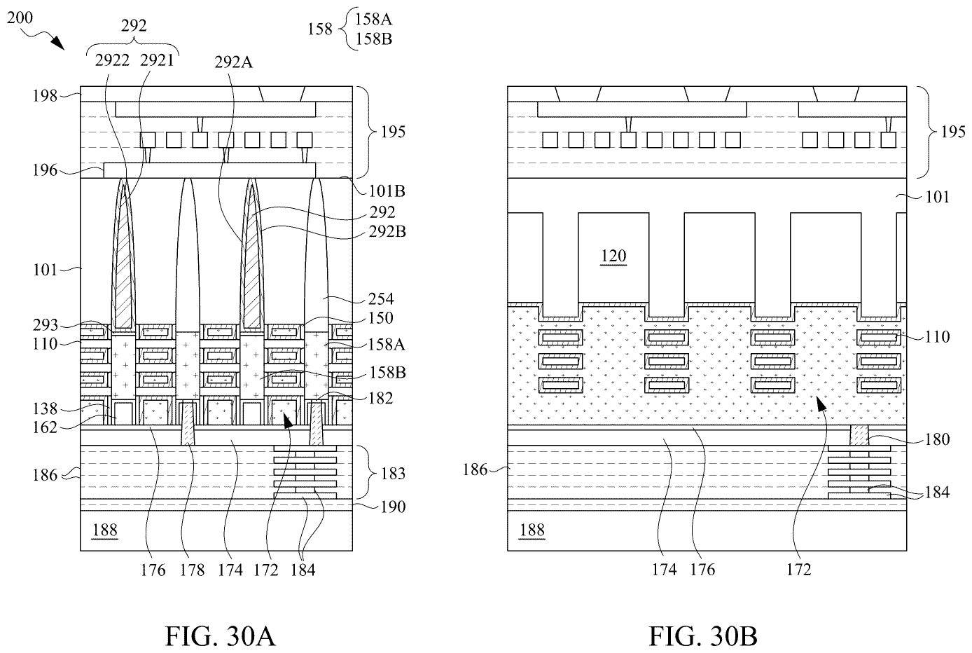

In FIGS. 30A and 30B, the backside contacts 292 are formed in the substrate 101, in accordance with some embodiments. For example, the backside contacts 292 may be formed by removing the isolate filling 254 from the surfaces exposed from the openings 223 and depositing materials of the backside contacts 292 into openings formed by the removal of the isolate filling 254. The removal of the isolate filling 254 may be the same as the etching process for forming the openings 191B as illustrated in FIG. 23A. Because the isolate filling 254 is connected to the source/drain regions 158, the removal of the isolate filling 254 may create openings self-aligned to the source/drain regions 158. Excess materials of the backside contacts 292 over the backside 101B of the substrate 101 may be removed by a planarization process, such as CMP or mechanical grinding. In some embodiments, the hard mask 222 is removed before the planarization process. In some embodiments, the backside contacts 292 includes a material same as those of the backside contacts 192, and the materials of the backside contacts 292 may be deposited by same processes similar to those for forming the backside contacts 192. For example, the backside contacts 292 may each include a barrier layer 2921, a filling material 292b over the barrier layer 2922, and a silicide region 293 in contact with the source/drain region 158. Although the above processes illustrate the use of the hard mask 222, the hard mask 222 can be omitted in accordance with some embodiments. For example, the backside contacts 292 are formed by removing the isolate filling 254 from the surfaces exposed from the backside 101B of the substrate 101 to create openings directed to the source/drain regions 158 and deposit conductive materials into the openings. Because the isolate filling 254 extends through the substrate 101, the etch process for forming the backside contacts 292, such as the etch processes of forming the openings 223, may be distant away from the gate structures 172 and may not damage the gates structures 172.

As illustrated in FIG. 30A, the backside contact 292 may include a first sidewall 292A and a second sidewall 292B opposite to each other. The first sidewall 292A and the second sidewall 292B may be straight or curved. In some embodiments, the first sidewall 292A is horizontally more distant away from the first source/drain region 159A along a vertical direction toward the source/drain region 158B, and the second sidewall 292B is horizontally closer to the source/drain region 158A along the vertical direction toward the source/drain region 158B. In an embodiment, a width of the backside contact 292 relatively adjacent to the backside 101B of the substrate 101 is smaller than a width of the backside contact relatively distant away from the backside 101B of the substrate 101. The backside interconnect structure 195 may be formed over the backside 101B of the substrate 101 and the backside contacts 292. The conductive features 196 (e.g., power rails) of the backside interconnect structure 195 may be electrically coupled to the source/drain regions 158 through the backside contacts 292.

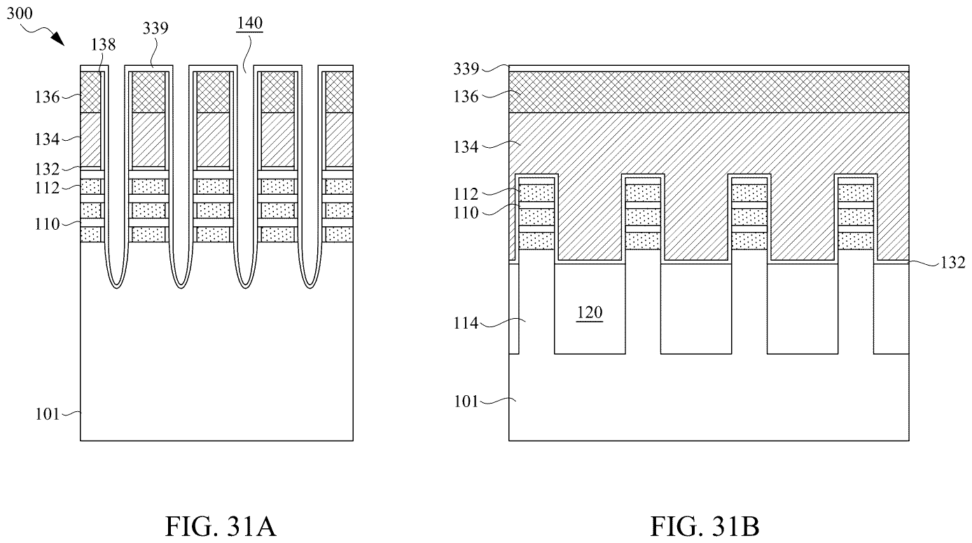

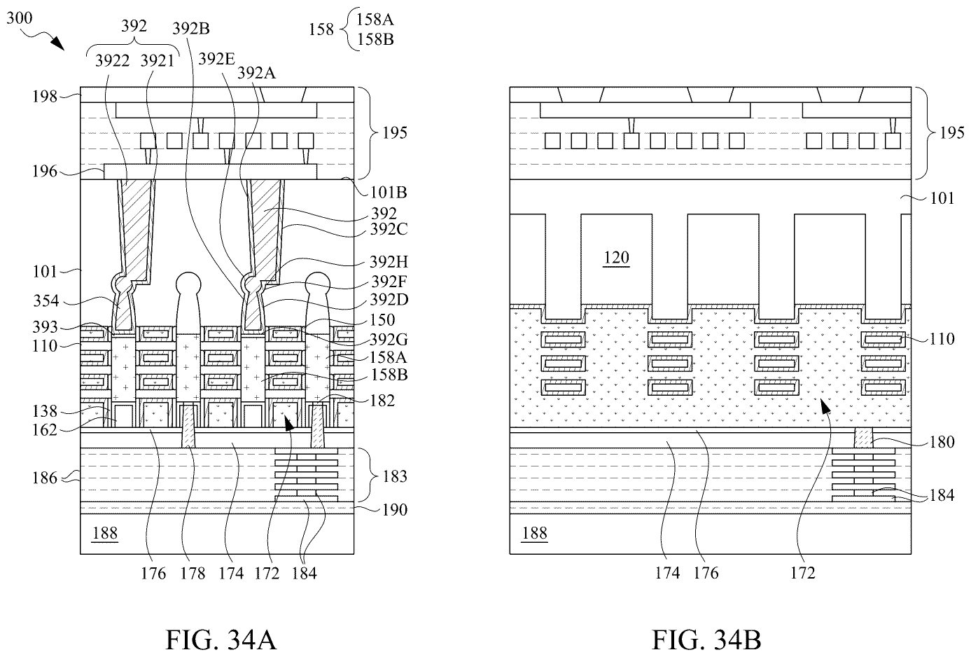

FIGS. 31A-34B illustrate cross-sectional views of intermediate steps in manufacturing a semiconductor device 300, in accordance with some embodiments. The semiconductor device 300 is similar to the semiconductor device 100 or 200 and can include any suitable features of the semiconductor device 100 or 200, wherein the like reference numeral refers to a like element. In some embodiments, the semiconductor device 300 includes backside contacts 392 (FIG. 34B) having extended depths and enlarged bottom widths formed in the substrate 101. The enlarged bottom widths of the backside contacts 392 may increase lithography misalignment tolerance when forming backside contacts 392.

Processing of manufacturing the semiconductor device 300 as illustrated in FIGS. 31A and 31B assumes the processing illustrated in FIGS. 7A and 7B performed prior. Accordingly, after the processing discussed above with reference to FIGS. 1-7B, processing may proceed to FIGS. 31A and 31B. In FIGS. 31A and 31B, a passivation layer 339 is formed in the first openings 140, in accordance with some embodiments. The passivation layer 339 may be formed on sidewalls of the first openings 140 while exposing the bottom portions of the first openings 140. For example, a conformal dielectric layer may be deposited in the first openings 140 by a suitable method, such as ALD, PECVD, LPCVD, or other suitable methods. An anisotropic etch process (e.g., RIE, NBE, or a combination thereof) may then be performed to remove the bottom portions of the conformal dielectric layer, thereby forming the passivation layer 339 that includes an opening 340 exposing underlying substrate 101. In an embodiment, a portion of the conformal dielectric layer adjacent to top surface of hard mask 136 while removing the bottom portions of conformal dielectric layer.

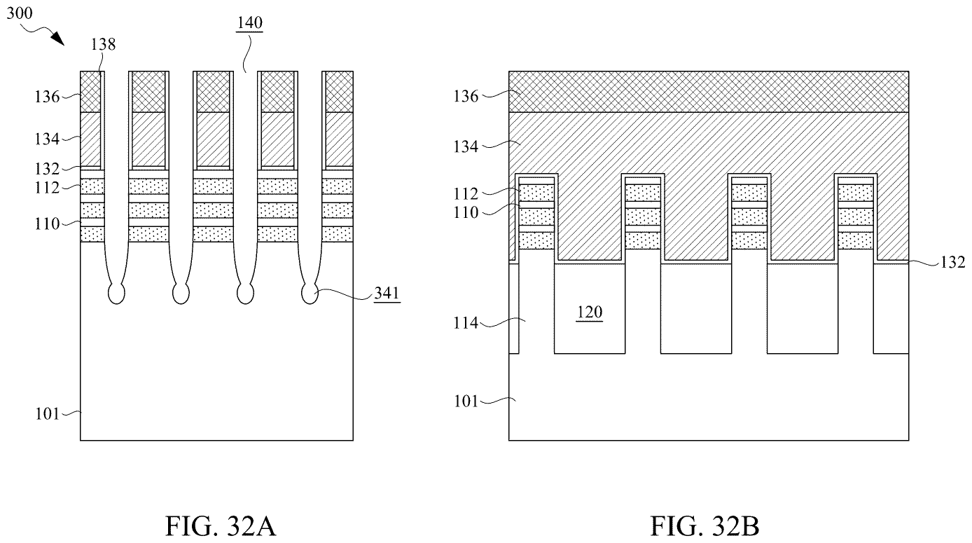

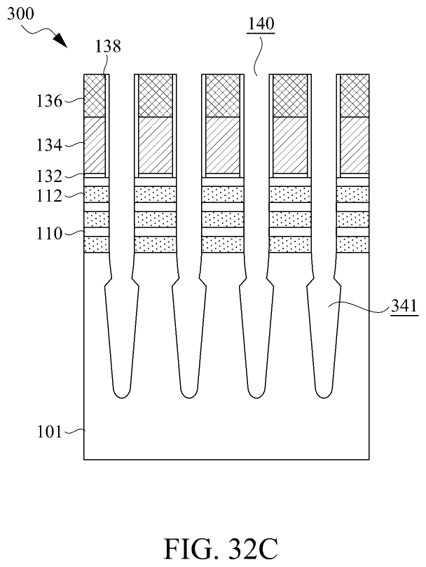

In FIGS. 32A and 32B, an isotropic process is performed to etch the underlying substrate 101 through the openings 340 of the passivation layer 339, thereby forming openings 341 having an enlarged bottom width, in accordance with some embodiments. Because the isotropic process may include lateral etch, the openings 341 may be wider than the bottom width of the first openings 140 (or the bottom width of the openings 340). In some embodiments, the passivation layer 339 is removed after the openings 341 are formed. For example, the passivation layer 339 may be removed by an etch process using an etchant highly selective to the passivation layer 339. Although FIG. 32A illustrates a circle-like cross-section, the openings 341 may include other shapes. For example, the openings 341 have a triangle-like shape or a tapered shape as illustrated in FIG. 32C.

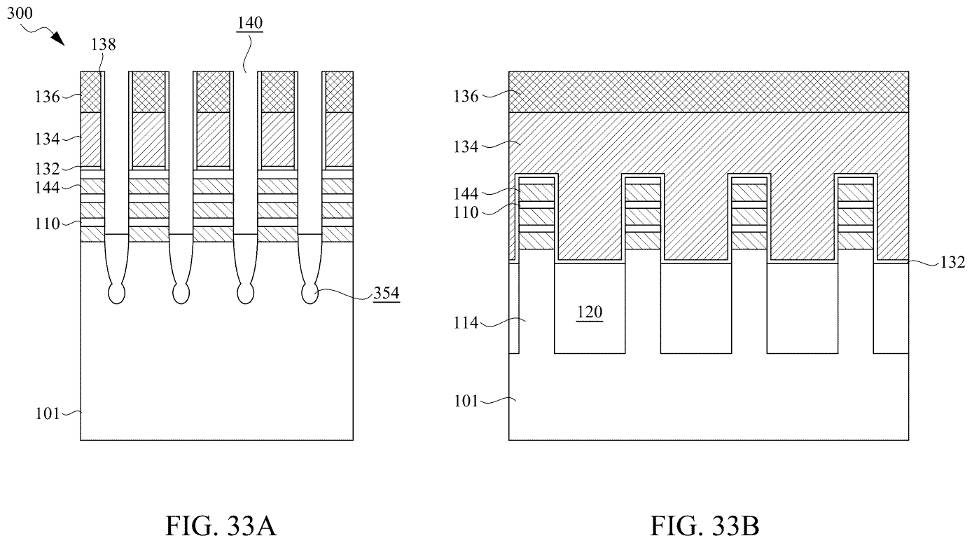

The processes of manufacturing the semiconductor device 300 with reference to FIGS. 9A-11B may then be performed, and processing may proceed to FIGS. 33A and 33B. In FIGS. 33A and 33B, an isolate filling 354 is deposited in the first openings 140 and the openings 341, in accordance with some embodiments. In an embodiment, the isolate filling 354 has an enlarged bottom width and a top surface vertically overlapping with the bottommost inner spacer 150. The isolate filling 354 may include a material similar to those of the isolate filling 354 and may be formed by processes similar to those of forming the isolate filling 154. The top surface of the isolate filling 354 may be planar, concave, or convex.

The processes of manufacturing the semiconductor device 300 with reference to FIGS. 13A-25B may then be performed, and processing may proceed to FIGS. 34A and 34B. In FIGS. 34A and 34B, the backside contacts 392 are formed in the substrate 101, in accordance with some embodiments. For example, the backside contacts 392 may be forming openings exposing the isolate filling 354 from backside 101B of substrate 101 by processes similar to those of forming the openings 191A, removing the isolate filling 354 by processes similar to those of forming the openings 191B, and then forming the conductive materials of the backside contacts 392 in the openings and the space created by the removal of the isolate filling 354 by processes similar to those of forming the backside contacts 192. For example, the backside contacts 392 may each include a barrier layer 3921, a filling material 3922 over the barrier layer 3921, and a silicide region 393 in contact with the source/drain region 158. In some embodiments, although the openings for exposing the isolate filling 354 may be misaligned from the source/drain regions 158, the removal of the isolate filling 354 may self-direct the openings to extend to align the source/drain regions 158. In addition, the enlarged bottom widths of the isolate filling 354 may further provide more tolerance for lithography variations and/or other process variations.

In some embodiments, the backside contact 392 includes a first sidewall 392A, a second sidewall 392B, a third sidewall 392C, a fourth sidewall 392D, a fifth sidewall 392E, and a sixth sidewall 392F. The first sidewall 392A may extend from the backside 101B of the substrate 101. In some embodiments, the first sidewall 392A is a straight sidewall and extends in a first direction. The second sidewall 392B may extend to the source/drain region 158. The second sidewall 392B may not extend in the first direction. In some embodiments, the second sidewall 392B may be a curved sidewall or a straight sidewall and does not extend in the first direction. In an example, the second sidewall 392B is horizontally more distant away from another source/drain region 158A along a vertical direction toward the source/drain region 158B. The third sidewall 392C may extend from the backside 101B of the substrate 101. In some embodiments, the third sidewall 392C is a straight sidewall and extends in a second direction. For example, the first sidewall 392A and the third sidewall 392C may be sidewalls opposite to each other. The fourth sidewall 392D is between the third sidewall 392C and the source/drain region 158A. The fourth sidewall 392D may not extend in the second direction. For example, the fourth sidewall 392D may be horizontally closer to another source/drain region 158A along a vertical direction toward the source/drain region 158B. In some embodiments, the third sidewall 392C is longer than the first sidewall 392A. In some embodiments, the second sidewall 392B is longer than the fourth sidewall 392D. The fifth sidewall 392E may connect the first sidewall 392A and the third sidewall 392C. The fifth sidewall 392E may be a curved sidewall. The sixth sidewall 392F may be between the third sidewall 392C and the fourth sidewall 392D. The sixth sidewall 392F may be a curved sidewall. In some embodiments, the sixth sidewall 392F may be horizontally distant away from another source/drain region 158B along the vertical direction toward the source/drain region 158B.

The backside contact 392 may also include a first bottom 392G connecting the second sidewall 392B and the fourth sidewall 392D. In some embodiments, the backside contact 392 also includes a second bottom 392H connecting the third sidewall 392C and the sixth sidewall 392F. The first bottom 392G and the second bottom 392H may extend in any direction, such as a horizontal direction illustrated in FIG. 34A or a non-horizontal direction. In an embodiment, the backside contact 392 extends into the source/drain region 158, and the first bottom 392G has a curved shape. In some embodiments, the second bottom 392H has a straight shape or a curved shape, depending on the etch profiles for forming the openings 191A.

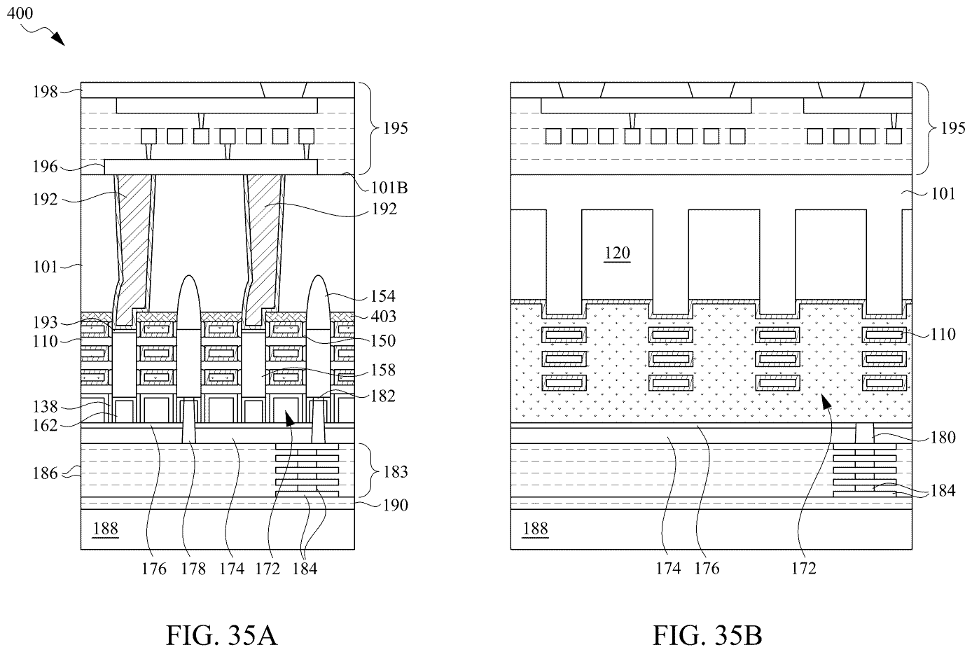

FIGS. 35A and 35B illustrate cross-sectional views of the semiconductor device 400, in accordance with some embodiments. The semiconductor device 400 is similar to the semiconductor device 100, 200, or 300, and can include any suitable features of the semiconductor device 100, 200, or 300, wherein the like reference numeral refers to a like element. The semiconductor device 400 may include a dielectric layer 403 between the bottommost gate structure 172 and the substrate 101. The dielectric layer 403 may be formed by providing a dielectric layer in the multilayer stack 102 between the bottommost second semiconductor layer 106 and the substrate 101 and being patterned with the first semiconductor layers 104 and the second semiconductor layers 106. The dielectric layer 403 may include a dielectric material different from the isolate filling 154 so that the dielectric layer 403 may not be substantially etched while removing the isolate filling 154. The dielectric layer 403 may act as a buffer for preventing the etch process for forming the openings 191A and/or the openings 191B from damaging the gate structure 172. For example, the semiconductor device 400 may be manufactured with reference to the processes illustrated in FIG. 2-25B. The etch process for forming the openings 191A may not need a time-mode etch.

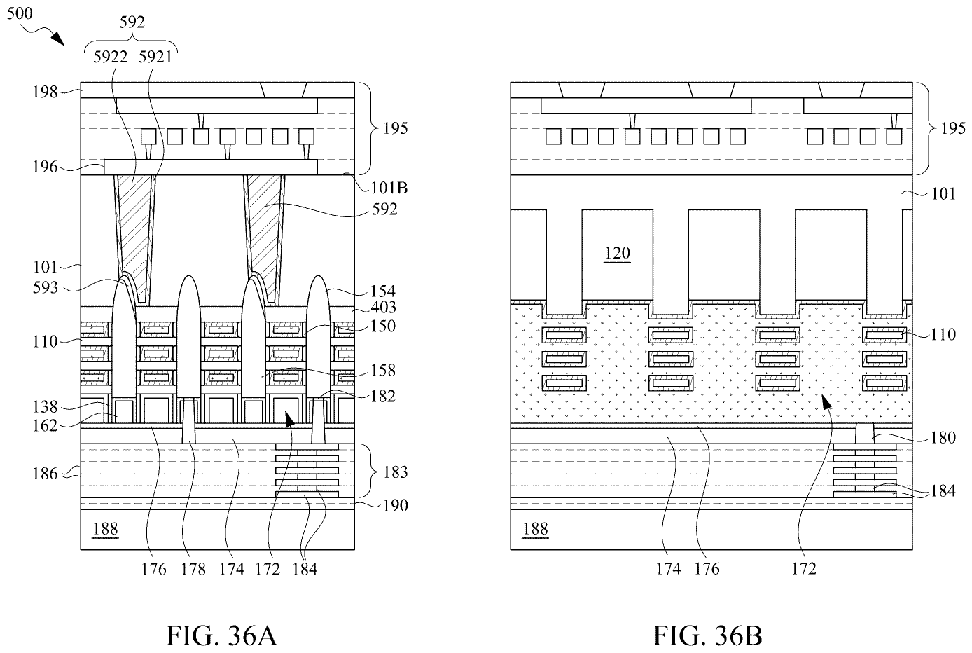

FIGS. 36A and 36B illustrate cross-sectional views of the semiconductor device 500, in accordance with some embodiments. The semiconductor device 500 is similar to the semiconductor device 500 and can include any suitable features of the semiconductor device 400, wherein the like reference numeral refers to a like element. In some embodiments, the isolate filling 154 is omitted when the dielectric layer 403 may provide sufficient protection for gate structures during the forming of backside contacts 192. The backside contacts 592 may include material similar to those of the backside contacts 192, such as including a barrier layer 5921, a filling material 5922 over the barrier layer 5921, and a silicide region 593. The backside contacts 592 may be formed by etching through substrate 101 from the backside 101B of the substrate 101 by an anisotropic etch process, such as RIE, NBE, or the like. Although the backside contacts 592 may overlap the gate structure 172 due to process variations (e.g., lithography errors), the backside contacts 692 may not damage the gate structure 172 because of the protection of the dielectric layer 403.

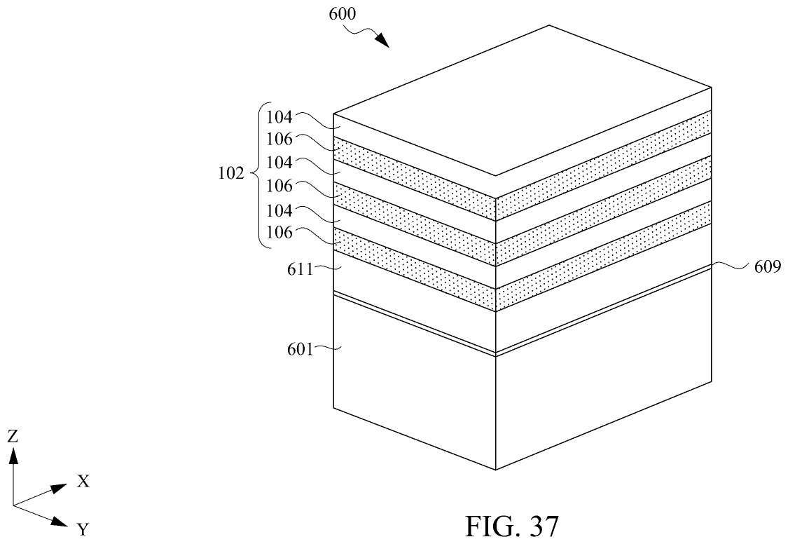

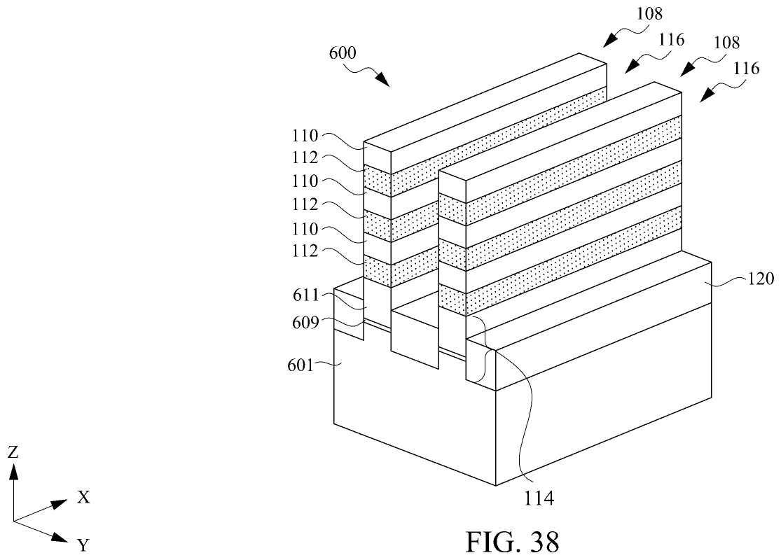

FIGS. 37 to 40B illustrate perspective views and cross-sectional views of a semiconductor device 600, in accordance with some embodiments. The semiconductor device 600 is similar to the semiconductor device 100 and can include any suitable features of the semiconductor device 200 to 500, wherein the like reference numeral refers to a like element. In FIG. 37, the substrate 601 is similar to substrate 101 and further includes a first epitaxial layer 609 and a second epitaxial layer 611 disposed below the multilayer stack 102, in accordance with some embodiments. The first epitaxial layer 609 may include a material similar to the second semiconductor material of the second semiconductor layers 106 such as SiGe, and the second epitaxial layer 611 may include a material similar to the first semiconductor material of the first semiconductor material of the first semiconductor layers 104 such as Si. In FIG. 38, processes similar to those illustrated in FIGS. 2 to 4 are then performed, and the fins 114 are formed between adjacent isolation structures 120. In some embodiments, each fin 114 includes the first epitaxial layer 609 and the second epitaxial layer 611.

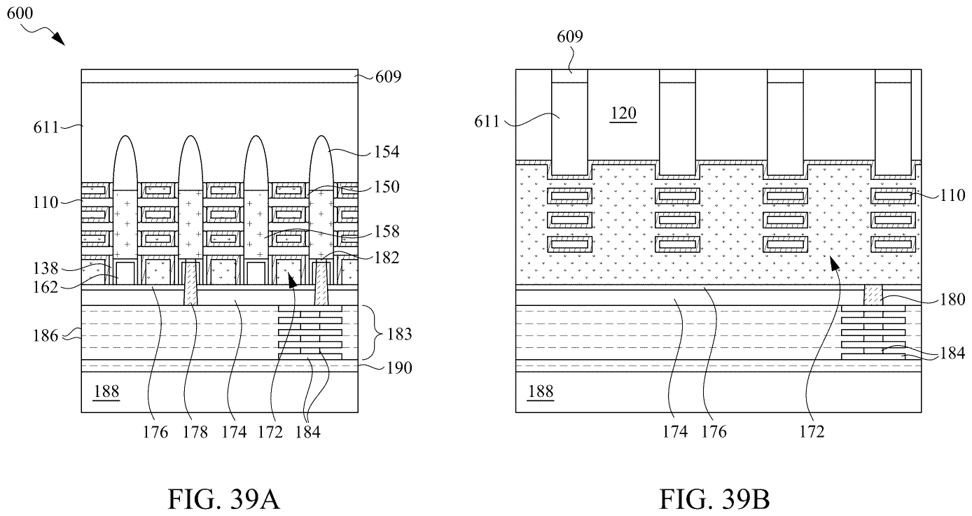

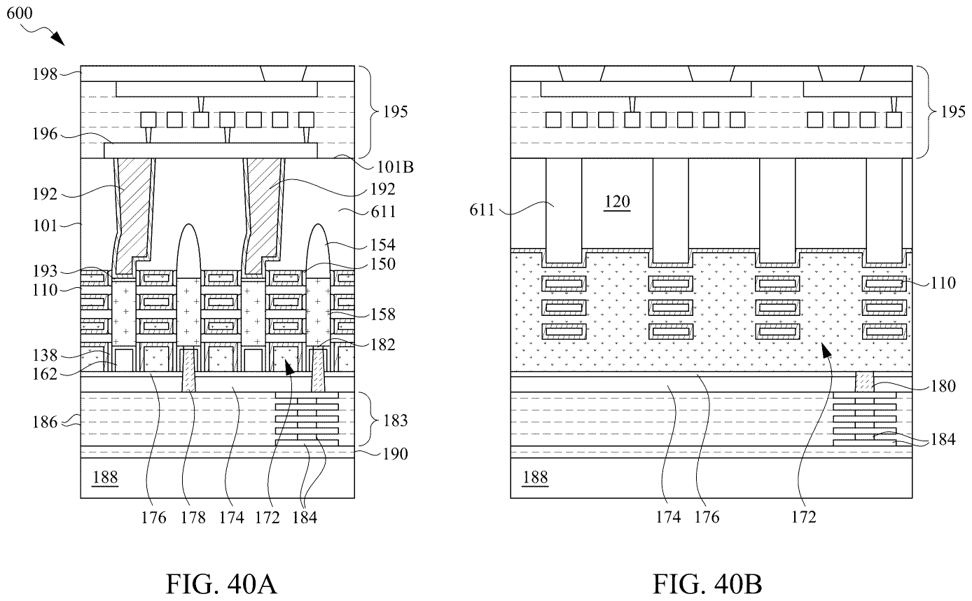

Processes similar to those illustrated in FIGS. 5 to 21B are performed, and the resulting structures of the semiconductor device 600 are shown in FIGS. 39A and 39B, in accordance with some embodiments. The first epitaxial layer 609 may be used as an etch top layer for the substrate thinning process. Thus, the remaining thickness of the substrate 101 may be decided by the position of the first epitaxial layer 609. In some embodiments, a part of the isolation regions 120 is also removed. Processes similar to those illustrated in 22A to 25B are performed, and the resulting structures of the semiconductor device are shown in FIGS. 40A and 40B, in accordance with some embodiments. The first epitaxial layer 609 may be further used as a hard mask to form openings 191 for the backside contacts 192. In some embodiments, the first epitaxial layer 609 may be consumed during the formation of the openings 191 or removed by an etch process after the openings 191 are formed.

Embodiments of the present disclosure provide a semiconductor device including self-aligned backside contacts formed in the substrate and electrically coupled to source/drain regions. The self-aligned backside contacts formed in a self-aligned manner can effectively reduce the risks of damaging gate structures or forming shorts between the backside contacts and gate structures. In some embodiments, the formation of the self-aligned backside contacts includes etching an isolate filling formed between the substrate and the source/drain regions, and the risks described above may also be reduced by varying shapes of the isolate filling or adding a dielectric layer between the substrate and the gate structures.

An embodiment is a semiconductor device that includes a substrate having a frontside and a backside opposite to the frontside of the substrate; a channel region disposed between a first source/drain region and a second source/drain region and over the frontside of the substrate; a gate structure disposed over the channel region; and a first contact disposed in the substrate, wherein the first contact includes a first sidewall extending from the backside of the substrate and a second sidewall extending to the first source/drain region, wherein the first sidewall and the second sidewall are on a same side of the first contact, wherein the second sidewall is horizontally more distant away from the second source/drain region along a vertical direction from the backside of the substrate toward the first source/drain region. In an embodiment, the first sidewall is horizontally closer to the second source/drain region along the vertical direction from the backside of the substrate toward the first source/drain region. In an embodiment, the first sidewall is a straight sidewall, and the second sidewall is a curved sidewall. In an embodiment, the first contact further includes a third sidewall, a fourth sidewall, and a first bottom connecting the third sidewall and the fourth sidewall, wherein the third sidewall extends from the backside of the substrate, and the fourth sidewall extends to the first source/drain region. In an embodiment, the fourth sidewall is horizontally closer to the second source/drain region along the vertical direction from the backside of the substrate toward the first source/drain region. In an embodiment, the semiconductor device further includes an isolate filling disposed between the second source/drain region and the substrate. In an embodiment, the semiconductor device further includes a second contact disposed over the frontside of the second source/drain region and electrically coupled to the second source/drain region. In an embodiment, a portion of the gate structure is disposed between the substrate and the channel region, wherein the semiconductor device further includes a dielectric layer disposed between the portion of the gate structure and the substrate.

Another embodiment is a semiconductor device that includes a substrate having a frontside and a backside opposite to the frontside of the substrate; a channel region disposed over the frontside of the substrate and between a first epitaxial region and a second epitaxial region; a gate structure disposed over the channel region; a backside contact disposed in the substrate, wherein the backside contact includes a first sidewall extending from the backside of the substrate, a second sidewall extending to the first epitaxial region, a third sidewall opposite to the first sidewall, and a fourth sidewall opposite to the second sidewall, wherein the second sidewall and the third sidewall are horizontally more distant away from the second source/drain region along a vertical direction from the backside of the substrate toward the first source/drain region; a frontside contact disposed over the frontside of the substrate and electrically coupled to the second epitaxial region; and a backside interconnect structure disposed over the backside of the substrate and including a conductive feature electrically coupled to the first epitaxial region through the backside contact. In an embodiment, the fourth sidewall overlaps the gate structure in a plan view. In an embodiment, the first sidewall and the fourth sidewall are closer to the second source/drain region along the vertical direction from the backside of the substrate toward the first source/drain region. In an embodiment, the backside contact further includes a fifth sidewall connecting the first sidewall and the second sidewall. In an embodiment, the fifth sidewall is a curved sidewall. In an embodiment, the backside contact further includes a sixth sidewall connecting to the fourth sidewall and a first bottom connecting the third sidewall and the sixth sidewall. In an embodiment, the semiconductor device further includes an isolate filling disposed between the substrate and the second epitaxial region.

A further embodiment is a method for forming a semiconductor device. The method includes: forming a channel region between a first source/drain region and a second source/drain region and over a frontside of a substrate, wherein the substrate includes a backside opposite to the frontside of the substrate; forming a gate structure over the channel region; and forming a first contact in the substrate, wherein the first contact includes a first sidewall extending from the backside of the substrate and a second sidewall extending to the first source/drain region, wherein the first sidewall and the second sidewall are on a same side of the first contact, wherein the second sidewall is horizontally more distant away from the second source/drain region along a vertical direction from the backside of the substrate toward the first source/drain region. In an embodiment, forming the first contact includes: forming a first opening extending into the substrate from the frontside of the substrate; forming a first isolate filling in the first opening; forming the first source/drain region in the first opening and over the first isolate filling; performing a first etch process from the backside of the substrate to form a second opening exposing the first isolate filling; performing a second etch process to etch the first isolate filling from the second opening and form a third opening exposing the first source/drain region; and depositing a conductive material in the second opening and the third opening. In an embodiment, the method further includes: forming a fourth opening extending into the substrate from the frontside of the substrate; forming a second isolate filling in the fourth opening while forming the first isolate filling; and forming the second source/drain region in the fourth opening and over the second isolate filling, wherein the second isolate filling is not etched while forming the first contact. In an embodiment, the method further includes forming a second contact disposed over the frontside of the substrate and electrically coupled to the second source/drain region. In an embodiment, the first sidewall is horizontally closer to the second source/drain region along the vertical direction from the backside of the substrate toward the first source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate having a frontside and a backside opposite to the frontside of the substrate;
a channel region disposed between a first source/drain region and a second source/drain region and over the frontside of the substrate;
a gate structure disposed over the channel region; and
a first contact disposed in the substrate, wherein the first contact comprises a first sidewall extending from the backside of the substrate and a second sidewall (192B) extending to the first source/drain region, wherein the first sidewall and the second sidewall are on a same side of the first contact, wherein the second sidewall is horizontally more distant away from the second source/drain region along a vertical direction from the backside of the substrate toward the first source/drain region.

2. The semiconductor device of claim 1, wherein the first sidewall is horizontally closer to the second source/drain region along the vertical direction from the backside of the substrate toward the first source/drain region.

3. The semiconductor device of claim 2, wherein the first sidewall is a straight sidewall, and the second sidewall is a curved sidewall.

4. The semiconductor device of claim 1, wherein the first contact further comprises a third sidewall, a fourth sidewall, and a first bottom connecting the third sidewall and the fourth sidewall, wherein the third sidewall extends from the backside of the substrate, and the fourth sidewall extends to the first source/drain region.

5. The semiconductor device of claim 4, wherein the fourth sidewall is horizontally closer to the second source/drain region along the vertical direction from the backside of the substrate toward the first source/drain region.

6. The semiconductor device of claim 1, further comprising an isolate filling disposed between the second source/drain region and the substrate.

7. The semiconductor device of claim 6, further comprising a second contact disposed over the frontside of the second source/drain region and electrically coupled to the second source/drain region.

8. The semiconductor device of claim 1, wherein a portion of the gate structure is disposed between the substrate and the channel region, wherein the semiconductor device further comprises a dielectric layer disposed between the portion of the gate structure and the substrate.

9. A semiconductor device, comprising:
a substrate having a frontside and a backside opposite to the frontside of the substrate;
a channel region disposed over the frontside of the substrate and between a first epitaxial region and a second epitaxial region;
a gate structure disposed over the channel region;
a backside contact disposed in the substrate, wherein the backside contact comprises a first sidewall extending from the backside of the substrate, a second sidewall extending to the first epitaxial region, a third sidewall opposite to the first sidewall, and a fourth sidewall opposite to the second sidewall, wherein the second sidewall and the third sidewall are horizontally more distant away from the second source/drain region along a vertical direction from the backside of the substrate toward the first source/drain region;
a frontside contact disposed over the frontside of the substrate and electrically coupled to the second epitaxial region; and
a backside interconnect structure disposed over the backside of the substrate and comprising a conductive feature electrically coupled to the first epitaxial region through the backside contact.

10. The semiconductor device of claim 9, wherein the fourth sidewall overlaps the gate structure in a plan view.

11. The semiconductor device of claim 9, wherein the first sidewall and the fourth sidewall are closer to the second source/drain region along the vertical direction from the backside of the substrate toward the first source/drain region.

12. The semiconductor device of claim 9, wherein the backside contact further comprises a fifth sidewall connecting the first sidewall and the second sidewall.

13. The semiconductor device of claim 12, wherein the fifth sidewall is a curved sidewall.

14. The semiconductor device of claim 9, wherein the backside contact further comprises a sixth sidewall connecting to the fourth sidewall and a first bottom connecting the third sidewall and the sixth sidewall.

15. The semiconductor device of claim 9, further comprising an isolate filling disposed between the substrate and the second epitaxial region.

16. A method of forming a semiconductor device, the method comprising:
forming a channel region between a first source/drain region and a second source/drain region and over a frontside of a substrate, wherein the substrate comprises a backside opposite to the frontside of the substrate;
forming a gate structure over the channel region; and
forming a first contact in the substrate, wherein the first contact comprises a first sidewall extending from the backside of the substrate and a second sidewall extending to the first source/drain region, wherein the first sidewall and the second sidewall are on a same side of the first contact, wherein the second sidewall is horizontally more distant away from the second source/drain region along a vertical direction from the backside of the substrate toward the first source/drain region.

17. The method of claim 16, wherein forming the first contact comprises:
forming a first opening extending into the substrate from the frontside of the substrate;
forming a first isolate filling in the first opening;
forming the first source/drain region in the first opening and over the first isolate filling;
performing a first etch process from the backside of the substrate to form a second opening exposing the first isolate filling;
performing a second etch process to etch the first isolate filling from the second opening and form a third opening exposing the first source/drain region; and
depositing a conductive material in the second opening and the third opening.

18. The method of claim 17, further comprising:
forming a fourth opening extending into the substrate from the frontside of the substrate;
forming a second isolate filling in the fourth opening while forming the first isolate filling; and
forming the second source/drain region in the fourth opening and over the second isolate filling, wherein the second isolate filling is not etched while forming the first contact.

19. The method of claim 18, further comprising forming a second contact disposed over the frontside of the substrate and electrically coupled to the second source/drain region.

20. The method of claim 17, wherein the first sidewall is horizontally closer to the second source/drain region along the vertical direction from the backside of the substrate toward the first source/drain region.
